(19) United States
(12) Patent Application Publication
(10) Pub. No.: US 2015/0194637 A1
(43) Pub. Date: Jul. 9, 2015

(54) METHOD FOR FORMING SILICON NITRIDE FILM, AND APPARATUS FOR FORMING SILICON NITRIDE FILM

(71) Applicant: TOKYO ELECTRON LIMITED, Tokyo (JP)

(72) Inventor: Hiraku Ishikawa, Miyagi (JP)

(73) Assignee: TOKYO ELECTRON LIMITED, Tokyo (JP)

(21) Appl. No.: 14/422,407

(22) PCT Filed: Aug. 9, 2013
(86) PCT No.: PCT/JP2013/071734

§ 371 Date: Feb. 19, 2015

(30) Foreign Application Priority Data
Aug. 23, 2012 (JP) 2012-184566
Apr. 12, 2013 (JP) 2013-084241

(51) Int. Cl. H01L 51/56; C23C 16/511; C23C 16/50; C23C 16/455; H01L 51/52; C23C 16/52

(52) U.S. Cl. CPC H01L 51/56; H01L 51/5253; C23C 16/52; C23C 16/50; C23C 16/455; C23C 16/511

(57) ABSTRACT

Provided is a method for forming a silicon nitride film on a substrate accommodated in a processing container. The method includes: supplying a processing gas including a silane-based gas, nitrogen gas, and hydrogen gas or ammonia gas to the processing container; forming the silicon nitride film on the substrate by exciting the processing gas to generate plasma and performing a plasma processing by the plasma; and applying a bias electric field to a part of the silicon nitride film by intermittently performing an ON/OFF control of a high frequency power source during or after the forming of the silicon nitride film.

### TECHNICAL FIELD

Various aspects and exemplary embodiments of the present disclosure relate to a method for forming a silicon nitride film, a method for manufacturing an organic electronic device, and an apparatus for forming a silicon nitride film.

### BACKGROUND

Recently, an organic electro luminescence (EL) device that is a light emitting device using an organic compound has been developed. The organic EL has advantages, for example, in that its power consumption is low since it is self-luminous and it is excellent in viewing angle as compared to, for example, a liquid crystal display (LCD).

The most basic structure of the organic EL device is a sandwich structure formed by laminating an anode (positive electrode) layer, a light emitting layer, and a cathode (negative electrode) layer one on another on a glass substrate. Among the layers, the light emitting layer is sensitive to moisture or oxygen. When moisture or oxygen is mixed in the light emitting layer, the characteristic of the light emitting layer varies which may generate a non-light emission point (dark spot).

For this reason, when manufacturing an organic electronic device including an organic EL device, sealing of the organic EL device is performed so as to prevent external moisture from infiltrating into the device. That is, when manufacturing the organic electronic device, an anode layer, a light emitting layer, and a cathode layer are sequentially formed on a glass substrate and, in addition, a layer of sealing film is formed thereon.

For example, a silicon nitride (SiN) film is used as the sealing film described above. The silicon nitride film is formed by, for example, plasma chemical vapor deposition (CVD). For example, the silicon nitride film is formed using plasma generated by exciting a processing gas including silane (SiH₄) gas or nitrogen (N₂) gas by a microwave power.

### PRIOR ART DOCUMENT

### Patent Document

Patent Document 1: Japanese Patent Laid-Open Publication No. 2005-339828

### SUMMARY OF THE INVENTION

### Problems to be Solved

However, the related art has not taken an issue of improving the sealing performance of the silicon nitride film serving as a sealing film into consideration. That is, when the silicon nitride film is merely formed as in the related art, pinholes may be generated in the silicon nitride film. When pinholes are generated in the silicon nitride film, moisture or oxygen may infiltrate into the organic EL device through the pinholes. As a result, in the related art, the sealing performance of the silicon nitride film serving as a sealing film may deteriorate.

### Means to Solve the Problems

A method for forming a silicon nitride film related to one aspect of the present disclosure is a silicon nitride film forming method for forming the silicon nitride film on a substrate accommodated in a processing container. The silicon nitride film forming method supplies a processing gas including a silane-based gas, nitrogen gas, and hydrogen gas or ammonia gas to the processing container. The silicon nitride film forming method forms the silicon nitride film on the substrate by exciting the processing gas to generate plasma and performing a plasma processing by the plasma. The silicon film forming method applies a bias electric field to a part of the silicon nitride film by intermittently performing an ON/OFF control of a high frequency power source during or after forming the silicon nitride film.

### Effect of the Invention

According to various aspects and exemplary embodiments of the present disclosure, a method for forming a silicon nitride film, a method for manufacturing an organic electronic device, and an apparatus for forming a silicon nitride film, which are capable of improving the sealing performance of a silicon nitride film serving as a sealing film, may be implemented.

### BRIEF DESCRIPTION OF THE DRAWINGS

FIG. 1 is an explanatory view illustrating a schematic configuration of a substrate processing system according to an exemplary embodiment.

FIG. 2 is an explanatory view illustrating a process of manufacturing an organic EL device according to an exemplary embodiment.

FIG. 3 is a vertical cross-sectional view illustrating a schematic configuration of a plasma film forming apparatus according to an exemplary embodiment.

FIG. 4 is a plan view illustrating a raw material gas supply structure according to an exemplary embodiment.

FIG. 5 is a plan view illustrating a plasma excitation gas supply structure according to an exemplary embodiment.

FIG. 6 is a graph illustrating a relationship between a supply flow rate of hydrogen gas and a wet etch rate of a silicon nitride film in a case where a plasma film forming method according to an exemplary embodiment is used.

FIG. 7 is a graph illustrating a relationship between a supply flow rate of hydrogen gas and film stress of a silicon nitride film in a case where a plasma film forming method according to an exemplary embodiment is used.

FIG. 8 is a graph illustrating a relationship between a power of microwaves and film stress of a silicon nitride film in a case where a plasma film forming method according to an exemplary embodiment is used.

FIG. 9 is an explanatory view comparing a case where a silicon nitride film is formed using a processing gas including silane gas, nitrogen gas, and hydrogen gas according to an exemplary embodiment with a case where a silicon nitride film is formed using a processing gas including silane gas and ammonia gas according to the related art;

FIG. 10 is a plan view illustrating a raw material gas supply structure according to another exemplary embodiment.

FIG. 11 is a cross sectional view illustrating a raw material gas supply pipe according to another exemplary embodiment.

FIG. 12 is a cross sectional view illustrating a raw material gas supply pipe according to another exemplary embodiment.

FIG. 13 is a time chart of respective conditions in a first film forming example of a SiN film and a view illustrating film forming states at respective timings.

FIG. 14 is a time chart of respective conditions in a second film forming example of a SiN film and a view illustrating film forming states at respective timings.

FIG. 15 is a time chart of respective conditions in a third film forming example of a SiN film and a view illustrating film forming states at respective timings.

FIG. 16 is a time chart of respective conditions in a fourth film forming example of a SiN film and a view illustrating film forming states at respective timings.

FIG. 17 is a time chart of respective conditions in a fifth film forming example of a SiN film and a view illustrating film forming states at respective timings.

FIG. 18 is a view illustrating processing results of Comparative Example 1 and Example 1.

### DETAILED DESCRIPTION TO EXECUTE THE INVENTION

Hereinafter, exemplary embodiments of the present disclosure will be described with reference to the accompanying drawings. In addition, in the present specification and drawings, the components having substantially the same functional configurations will be given the same reference numerals and redundant descriptions will be omitted.

A method for forming a silicon nitride film is a silicon nitride film forming method for forming the silicon nitride film on a substrate accommodated in a processing container. The silicon nitride film forming method supplies a processing gas including a silane-based gas, nitrogen gas, and hydrogen gas or ammonia gas to the processing container. The silicon nitride film forming method forms the silicon nitride film on the substrate by exciting the processing gas to generate plasma and performing a plasma processing by the plasma. The silicon film forming method applies a bias electric field to a part of the silicon nitride film by intermittently performing an ON/OFF control of a high frequency power source during or after the forming of the silicon nitride film.

In the silicon nitride film forming method of an exemplary embodiment, in the supplying of the processing gas to the processing container, supply of at least the silane-based gas among the gases included in the processing gas is intermittently performed, and in the applying of the bias electric field to a part of the silicon nitride film, the bias electric field is applied to the part of the silicon nitride film by performing the ON control of the high frequency power source during the forming of the silicon nitride film in which the supply of the silane-based gas is performed and performing the OFF control of the high frequency power source at a timing of stopping the supply of the silane-based gas.

In the silicon nitride film forming method of an exemplary embodiment, in the supplying of the processing gas to the processing container, supply of at least the silane-based gas among the gases included in the processing gas is intermittently repeated, and in the applying of the bias electric field to a part of the silicon nitride film, the bias electric field is applied to the part of the silicon nitride film by performing the ON control of the high frequency power source during the forming of the silicon nitride film in which the supply of the silane-based gas is performed and performing the OFF control of the high frequency power source during a predetermined period from at a timing of stopping the supply of the silane-based gas to a timing of restarting the supply of the silane-based gas.

In the silicon nitride film forming method of an exemplary embodiment, in the applying of the bias electric field to part of the silicon nitride film, the OFF control of the high frequency power source is performed at the timing of restarting the supply of the silane-based gas during the predetermined period.

In the silicon nitride film forming method of an exemplary embodiment, in the supplying of the processing gas to the processing container, supply of at least the silane-based gas among the gases included in the processing gas is intermittently repeated, and in the applying of the bias electric field to a part of the silicon nitride film, the bias electric field is applied to the part of the silicon nitride film by performing the ON control of the high frequency power source at a timing of stopping the supply of the silane-based gas and performing the OFF control of the high frequency power source during the forming of the silicon nitride film in which the supply of the silane-based gas is performed.

In the silicon nitride film forming method of an exemplary embodiment, a processing time of applying the bias electric field to a part of the silicon nitride film increases as a film thickness of the silicon nitride film increases.

In the silicon nitride film forming method of an exemplary embodiment, the silicon nitride film is used as a sealing film of an organic electronic device.

In the silicon nitride film forming method of an exemplary embodiment, a pressure within the processing container is maintained in a range of 10 Pa to 60 Pa during the plasma processing using the plasma.

In the silicon nitride film forming method of an exemplary embodiment, a supply flow rate of the hydrogen gas is controlled to control film stress of the silicon nitride film.

In the silicon nitride film forming method of an exemplary embodiment, the plasma is generated as the processing gas is excited by microwaves.

In the silicon nitride film forming method of an exemplary embodiment, a power of the microwaves is controlled to control film stress of the silicon nitride film.

In the silicon nitride film forming method of an exemplary embodiment, the processing gas includes a raw material gas to form the silicon nitride film and a plasma excitation gas to generate the plasma, and after the processing gas is stabilized to a desired processing condition, supply of a power of the microwaves (μ waves) is initiated to generate the plasma.

In the silicon nitride film forming method of an exemplary embodiment, a ratio of a supply flow rate of the nitrogen gas in relation to a supply flow rate of the silane-based gas in the processing gas to be supplied to the processing container ranges 1 to 1.5.

In an exemplary embodiment, a method for manufacturing an organic electronic device forms an organic device on a substrate, then supplies a processing gas including a silane-based gas, nitrogen gas, and hydrogen gas or ammonia gas to the processing container, forms the silicon nitride film on the substrate to form the organic device by exciting the processing gas to generate plasma and performing a plasma processing by the plasma, and applies a bias electric field to a part of the silicon nitride film by intermittently performing an ON/OFF control of a high frequency power source during or after the forming of the silicon nitride film.

In the organic electronic device manufacturing method of an exemplary embodiment, in the supplying of the processing gas to the processing container, supply of at least the silane-based gas among the gases included in the processing gas is intermittently performed, and in the applying of the bias electric field to a part of the silicon nitride film, the bias electric field is applied to the part of the silicon nitride film by performing the ON control of the high frequency power during the forming of the silicon nitride film in which the supply of the silane-based gas is performed and performing the OFF control of the high frequency power source at a timing of stopping the supply of the silane-based gas.

In the organic electronic device manufacturing method of an exemplary embodiment, in the supplying of the processing gas to the processing container, supply of at least the silane-based gas among the gases included in the processing gas is intermittently repeated, and in the applying of the bias electric field to a part of the silicon nitride film, the bias electric field is applied to the part of the silicon nitride film by performing the ON control of the high frequency power source during the forming of the silicon nitride film in which the supply of the silane-based gas is performed and performing the OFF control of the high frequency power source during a predetermined period from at a timing of stopping the supply of the silane-based gas to a timing of restarting the supply of the silane-based gas.

In the organic electronic device manufacturing method of an exemplary embodiment, in the applying of the bias electric field to part of the silicon nitride film, the OFF control of the high frequency power source is performed at the timing of restarting the supply of the silane-based gas during the predetermined period.

In the organic electronic device manufacturing method of an exemplary embodiment, in the supplying of the processing gas to the processing container, supply of at least the silane-based gas among the gases included in the processing gas is intermittently repeated, and in the applying of the bias electric field to a part of the silicon nitride film, the bias electric field is applied to the part of the silicon nitride film by performing the ON control of the high frequency power source at a timing of stopping the supply of the silane-based gas and performing the OFF control of the high frequency power source during the forming of the silicon nitride film in which the supply of the silane-based gas is performed.

In the organic electronic device manufacturing method of an exemplary embodiment, a processing time of applying the bias electric field to a part of the silicon nitride film increases as a film thickness of the silicon nitride film increases.

In the organic electronic device manufacturing method of an exemplary embodiment, a pressure within the processing container is maintained in a range of 10 Pa to 60 Pa during the plasma processing using the plasma.

In the organic electronic device manufacturing method of an exemplary embodiment, a supply flow rate of the hydrogen gas is controlled to control film stress of the silicon nitride film.

In the organic electronic device manufacturing method of an exemplary embodiment, the plasma is generated as the processing gas is excited by microwaves.

In the organic electronic device manufacturing method of an exemplary embodiment, a power of the microwaves is controlled to control film stress of the silicon nitride film.

In the organic electronic device manufacturing method of an exemplary embodiment, the processing gas includes a raw material gas to form the silicon nitride film and a plasma excitation gas to generate the plasma, and after the processing gas is stabilized to a desired processing condition, supply of a power of the microwaves (μ, waves) is initiated to generate the plasma.

In the organic electronic device manufacturing method of an exemplary embodiment, a ratio of a supply flow rate of the nitrogen gas in relation to a supply flow rate of the silane-based gas in the processing gas to be supplied to the processing container ranges 1 to 1.5.

In an exemplary embodiment, an apparatus for forming a silicon nitride film forms a silicon nitride film on a substrate. The silicon nitride film forming apparatus includes: a processing container configured to accommodate and process a substrate; a processing gas supply unit configured to supply a processing gas including a silane-based gas, nitrogen gas, and hydrogen gas or ammonia gas to the processing container; a plasma excitation unit configured to excite the processing gas so as to generate plasma; a high frequency power source configured to apply a bias electric field to the substrate; and a control unit configured to cause the processing gas supply unit to supply the processing gas including the silane-based gas, nitrogen gas, and hydrogen gas or ammonia gas, to cause the plasma excitation unit to generate plasma by exciting the processing gas so that a silicon nitride film is formed on the substrate by performing a plasma processing by the plasma, and to intermittently performs an ON/OFF control of the high frequency power surface during or after the formation of the silicon nitride film to applying the bias electric field to a part of the silicon nitride film.

In the silicon nitride film forming apparatus of an exemplary embodiment, the control unit causes the processing gas supply unit to intermittently performs supply of at least the silane-based gas among the gases included in the processing gas, and the control unit performs the ON control of the high frequency power during the forming of the silicon nitride film in which the supply of the silane-based gas is performed and performs the OFF control of the high frequency power source at a timing of stopping the supply of the silane-based gas so that the bias electric field is applied to the part of the silicon nitride film by performing.

In the silicon nitride film forming apparatus of an exemplary embodiment, the control unit causes the processing gas supply unit to perform supply of at least the silane-based gas among the gases included in the processing gas is intermittently repeated, and the control unit performs the ON control of the high frequency power source during the forming of the silicon nitride film in which the supply of the silane-based gas is performed and performs the OFF control of the high frequency power source during a predetermined period from at a timing of stopping the supply of the silane-based gas to a timing of restarting the supply of the silane-based gas so that the bias electric field is applied to the part of the silicon nitride film.

In the silicon nitride film forming apparatus of an exemplary embodiment, the control unit performs the OFF control of the high frequency power source at the timing of restarting the supply of the silane-based gas during the predetermined period.

In the silicon nitride film forming apparatus of an exemplary embodiment, the control unit causes the processing gas supply unit to intermittently perform supply of at least the silane-based gas among the gases included in the processing gas, and the control unit performs the ON control of the high frequency power source at a timing of stopping the supply of the silane-based gas and performs the OFF control of the high frequency power source during the forming of the silicon nitride film in which the supply of the silane-based gas is performed so that the bias electric field is applied to the part of the silicon nitride film.

In the silicon nitride film forming apparatus of an exemplary embodiment, a processing time of applying the bias electric field to a part of the silicon nitride film increases as a film thickness of the silicon nitride film increases.

In the silicon nitride film forming apparatus of an exemplary embodiment, the silicon nitride film is used as a sealing film of an organic electronic device.

In the silicon nitride film forming apparatus of an exemplary embodiment, the control unit controls the processing gas supply unit to maintain a pressure within the processing container in a range of 10 Pa to 60 Pa during the plasma processing using the plasma.

In the silicon nitride film forming apparatus of an exemplary embodiment, the control unit controls a supply flow rate of the hydrogen gas to control film stress of the silicon nitride film.

In the silicon nitride film forming apparatus of an exemplary embodiment, the plasma excitation unit supplies microwaves to excite the processing gas.

In the silicon nitride film forming apparatus of an exemplary embodiment, the control unit controls a power of the microwaves to control film stress of the silicon nitride film.

In the silicon nitride film forming apparatus of an exemplary embodiment, the processing gas includes a raw material gas to form the silicon nitride film and a plasma excitation gas to generate the plasma, and the control units controls the processing gas supply unit and the plasma excitation unit to initiate supply of a power of the microwaves (μ waves) is initiated to generate the plasma after the processing gas is stabilized to a desired processing condition.

In the silicon nitride film forming apparatus of an exemplary embodiment, the control unit controls the processing gas supply unit such that a ratio of a supply flow rate of the nitrogen gas in relation to a supply flow rate of the silane-based gas in the processing gas to be supplied to the processing container ranges 1 to 1.5.

In the silicon nitride film forming apparatus of an exemplary embodiment, the processing gas includes a raw material gas for forming the silicon nitride film and a plasma excitation gas for generating the plasma, the plasma excitation unit is provided in an upper portion of the processing container, a placing unit configured to place the substrate thereon is installed in a lower portion of the processing container, a plasma excitation gas supply structure and a raw material gas supply structure are provided between the plasma excitation unit and the placing unit, the plasma excitation gas supply structure and the raw material gas supply structure dividing the inside of the processing container and constituting the processing gas supply unit, the plasma excitation gas supply structure is formed with a plasma excitation gas supply port configured to supply the plasma excitation gas to the plasma excitation unit side region and an opening configured to allow the plasma generated in the plasma excitation unit side region to pass therethrough to the placing unit side region, and the raw material gas supply structure is formed with a raw material gas supply port configured to supply the raw material gas to the placing unit side and an opening configured to allow the plasma generated in the plasma excitation unit side region to pass therethrough to the placing unit side region.

In the silicon nitride film forming apparatus of an exemplary embodiment, the plasma excitation gas supply structure is located at a position within a distance of 30 mm from the plasma excitation unit.

In the silicon nitride film forming apparatus of an exemplary embodiment, the raw material gas supply port is formed toward a horizontal direction.

In the silicon nitride film forming apparatus of an exemplary embodiment, the raw material gas supply port is formed such that its inner diameter is enlarged from the inside toward the outside thereof in a tapered form.

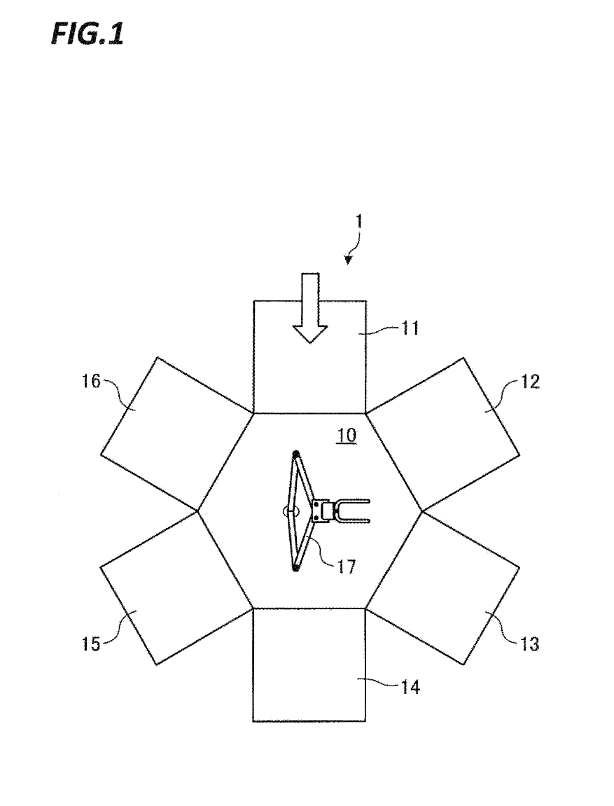

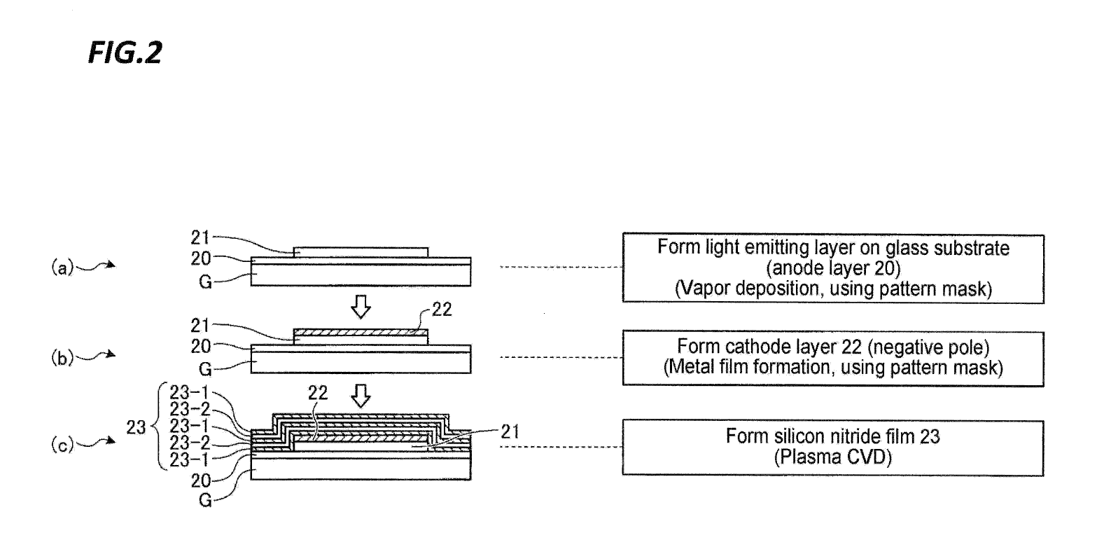

First, a method for manufacturing an organic electronic device according to an exemplary embodiment of the present disclosure will be described together with a substrate processing system for carrying out the manufacturing method. FIG. 1 is an explanatory view illustrating a schematic configuration of a substrate processing system 1 according to an exemplary embodiment. FIG. 2 is an explanatory view illustrating a process of manufacturing an organic EL device according to an exemplary embodiment. In the present exemplary embodiment, descriptions will also be made on a case where an organic EL device is manufactured as an organic electronic device.

As illustrated in FIG. 1, a cluster type substrate processing system 1 includes a conveyance chamber 10. The conveyance chamber 10 has, for example, a substantially polygonal shape (a hexagonal shape in the illustrated example) in a plan view, and is configured such that the inside thereof is hermetically sealed. A load-lock chamber 11, a cleaning apparatus 12, a vapor deposition apparatus 13, a metal film forming apparatus 14, a vapor deposition apparatus 15, and a plasma film forming apparatus 16 are arranged around the conveyance chamber 10 in this order in a clockwise rotation direction in a plan view.

A bendable, extendible and rotatable multi joint conveyance arm 17 is provided in the conveyance chamber 10. A glass substrate as a substrate is conveyed to the load-lock chamber 11 and each of the processing apparatuses 12 to 16 by the conveyance arm 17.

The load-lock chamber 11 is a vacuum conveyance chamber, of which the inside is maintained in a predetermined decompressed state, in order to convey the glass substrate conveyed from an atmospheric system, to the conveyance chamber 10 which is in a decompressed state.

Descriptions will be made in detail on a configuration of the plasma film forming apparatus 16. As for the other processing apparatuses such as, for example, the cleaning apparatus 12, the vapor deposition apparatus 13, the metal film forming apparatus 14, and the vapor deposition apparatus 15, conventional apparatuses may be used and thus, descriptions on the configurations thereof will be omitted. An inversion apparatus may be placed between the respective apparatuses as needed.

Next, descriptions will be made on a method for manufacturing an organic EL device which is performed in the substrate processing system 1 having the above-described configuration.

As illustrated in FIG. 2(a), an anode (positive electrode) layer 20 is formed in advance on the top surface of a glass substrate G. The anode layer 20 is formed of, for example, a transparent conductive material such as, for example, indium tin oxide (ITO). In addition, the anode layer 20 is formed on the top surface of the glass substrate G by, for example, sputtering. In a real device, a passive element or an active element is present on the glass substrate G, but is omitted in FIG. 2.

Then, after a surface of the anode layer 20 on the glass substrate G is cleaned in the cleaning apparatus 12, a light emitting layer (organic layer) 21 is formed on the anode layer 20 through vapor deposition in the vapor deposition apparatus 13, as illustrated in FIG. 2(a). The light emitting layer 21 has, for example, a multi-layered configuration in which a hole transport layer, a non-light emitting layer (electron block layer), a blue light emitting layer, a red light emitting layer, a green light emitting layer, and an electron transport layer, for example, are laminated one on another. Instead of the vapor deposition apparatus 13, the vapor deposition apparatus 15 may be used.

Subsequently, as illustrated in FIG. 2(b), a cathode (negative electrode) layer 22, which is formed of, for example, Ag or Al, is formed on the light emitting layer 21 in the metal film forming apparatus 14. The cathode layer 22 is formed on the light emitting layer 21 through a pattern mask by, for example, metal vapor deposition. The anode layer 20, the light emitting layer 21, and the cathode layer 22 constitute an organic EL device of the present disclosure. Hereinafter, the organic EL device of the present disclosure may also be briefly referred to as an “organic EL device”.

After the cathode layer 22 is formed, a silylation processing may be performed using a coupling agent, for example, and an extremely thin adhesion layer (not illustrated) may be formed on the cathode layer 22. The adhesion layer and the organic EL device are firmly adhered to each other, and the adhesion layer is also firmly adhered to a silicon nitride (SiN) film 23 to be described below.

Subsequently, as illustrated in FIG. 2(c), for example, the silicon nitride (SiN) film 23 serving as a sealing film is formed in the plasma film forming apparatus 16 to cover the periphery of the light emitting layer 21 and the cathode layer 22 and an exposed portion of the anode layer 20. The SiN film 23 is formed by, for example, a microwave plasma CVD method. Descriptions will be made in detail on the SiN film 23.

The organic EL device A manufactured as described above may emit light from the light emitting layer 21 when a voltage is applied between the anode layer 20 and the cathode layer 22. The organic EL device A may be applied to a display device or a surface emission device (e.g., a lighting light source), and may be used in various other electronic appliances.

Here, descriptions will be made in detail on the configuration of the SiN film 23 according to the present exemplary embodiment. As illustrated in FIG. 2, the SiN film 23 includes a first SiN film 23-1 and a second SiN film 23-2. More specifically, the first SiN film 23-1 and the second SiN film 23-2 are alternately laminated in multiple layers on the organic EL device in the order of the first SiN film 23-1, the second SiN film 23-2, the first SiN film 23-1, the second SiN film 23-2, and the first SiN film 23-1.

The first SiN film 23-1 is formed using plasma generated by the plasma film forming apparatus (described below). The second SiN film 23-2 is formed by applying a bias electric field using a high frequency power source of the plasma film forming apparatus during the film formation which is performed using plasma in the same manner as the first SiN film 23-1. In addition, the second SiN film 23-2 may be formed by applying the bias electric field using the high frequency power source of the plasma film forming apparatus after the film formation is performed using plasma generated by the plasma film forming apparatus.

As described above, the bias electric field is applied to the second SiN film 23-2, which is a part of the SiN film 23, by the high frequency power source, during or after the formation of the SiN film 23. As a result, ions in the plasma are drawn into the second SiN film 23-2. The ions in the plasma apply ion shock to the second SiN film 23-2. The formed second SiN film 23-2 is grown in a direction different from that of the first SiN film 23-1 by the ion shock. In other words, the second SiN film 23-2 and the first SiN film 23-1 are different in growth (deposition) direction (hereinafter, properly referred to as a “deposition direction”).

For example, when pinholes are generated in the SiN film, the second SiN film 23-2 may grow the generated pinholes in a nonlinear shape (e.g., a zigzag shape) since the second SiN film 23-2 has a deposition direction different from that of the first SiN film 23-1. For example, when moisture infiltrates from the outside, the moisture is efficiently captured (trapped) and does not reach the organic EL device since the generated pinholes have a nonlinear shape (e.g., a zigzag shape) and paths thereof are long. Accordingly, the SiN film of the organic EL device in the present exemplary embodiment may suppress the moisture, which has infiltrated from the outside, from infiltrating into the organic EL device. As a result, the SiN film of the organic EL device in the present exemplary embodiment may improve the sealing performance of the SiN film serving as a sealing film.

In addition, since the bias electric field is applied to the second SiN film 23-2 by the high frequency power source during or after the film formation, the film density of the second SiN film 23-2 becomes higher than that of the first SiN film 23-1. In addition, since the bias electric field is applied to the second SiN film 23-2 by the high frequency power source during or after the film formation, the refraction index of the second SiN film 23-2 becomes higher than that of the first SiN film 23-1.

In addition, since the bias electric field is applied to the second SiN film 23-2 by the high frequency power source during or after film formation in which no bias power is applied to the first SiN film 23-1 by the high frequency power source, the first SiN film 23-1 is subjected to less stress than the second SiN film 23-2. Accordingly, the first SiN film 23-1 serves as a stress alleviation layer to alleviate the stress of the entire SiN film 23. Thus, the present exemplary embodiment may prevent excessive stress from being applied to the organic EL device by forming the first SiN film 23-1, to which no bias power is applied by the high frequency power source. As a result, the present exemplary embodiment may prevent the SiN film 23 serving as a sealing film from peeling off from the organic EL device or being damaged in the vicinity of an interface of the organic EL device.

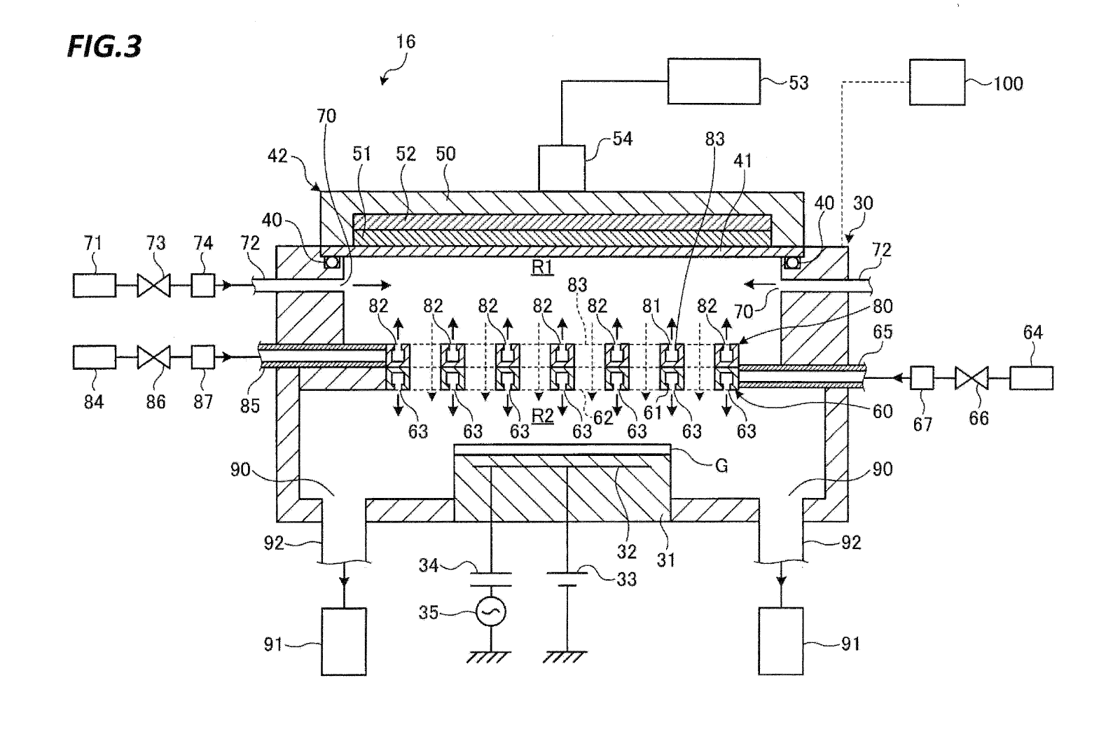

Subsequently, descriptions will be made on a method for forming the SiN film 23 as described above, together with the plasma film forming apparatus 16 that forms the SiN film 23. FIG. 3 is a vertical cross-sectional view illustrating a schematic configuration of the plasma film forming apparatus according to an exemplary embodiment. The plasma film forming apparatus 16 of the present exemplary embodiment is a CVD apparatus that generates plasma using a radial line slot antenna.

The plasma film forming apparatus 16 includes, for example, a top-opened and bottom-closed cylindrical processing container 30. The processing container 30 is formed of, for example, an aluminum alloy. In addition, the processing container 30 is grounded. A placing table 31 is provided at a substantially central portion of the bottom of the processing container 30 in which the placing table 31 serves as a placing unit on which, for example, a glass substrate G is placed.

The placing table 31 includes an electrode plate 32 embedded therein. The electrode plate 32 is connected to a direct current (DC) power source 33 provided in the outside of the processing container 30. The DC power source 33 generates an electrostatic force on the surface of the placing table 31 so as to elastically attract the glass substrate G to the placing table 31. In addition, a high frequency power source 35 is connected to the placing table 31 via a matcher 34. The frequency of the high frequency power source 35 is in a range of 400 KHz to 13.56 MHz. The high frequency power source 35 may apply a bias electric field to the placing table 31 by outputting a high frequency power. In addition, the high frequency power source 35 may apply a bias electric field to the glass substrate G placed on the placing table 31 and a film formed on the glass substrate G by outputting the high frequency power.

A dielectric window 41 is provided in the top opening of the processing container 30 via a sealing member 40 such as, for example, an O-ring, to assure airtightness. The inside of the processing container 30 is closed by the dielectric window 41. A radial line slot antenna 42 is provided on the top of the dielectric window 41 in which the radial line slot antenna 42 serves as a plasma excitation unit that supplies microwaves for plasma generation. In addition, the dielectric window 41 is formed of, for example, alumina (Al₂O₃). In this case, the dielectric window 41 is resistant to nitrogen trifluoride (NF₃) gas for use in dry cleaning. In addition, in order to improve the resistance to nitrogen trifluoride gas, the alumina surface of the dielectric window 41 may be coated with yttria (Y₂O₃), spinel (MgAl₂O₄), or aluminum nitride (AlN).

The radial line slot antenna 42 has a substantially cylindrical bottom-opened antenna body 50. A disc-shaped slot plate 51 formed with a plurality of slots is installed in an opening formed in the bottom of the antenna body 50. A dielectric plate 52 formed of a low-loss dielectric material is installed on the top of the slot plate 51 in the antenna body 50. A coaxial waveguide 54 is connected to the top surface of the antenna body 50 in which the coaxial waveguide is in communication with a microwave oscillator 53. The microwave oscillator 53 serves as a plasma excitation unit that excites a processing gas transported to the processing container 30 to generate plasma. The microwave oscillator 53 may be installed in the outside of the processing container 30 and oscillate microwaves having a predetermined frequency, for example, 2.45 GHz with respect to the radial line slot antenna 42. With this configuration, microwaves oscillated from the microwave oscillator 53 are propagated to the radial line slot antenna 42 and compressed and shortened in wavelength in the dielectric plate 52. Thereafter, circular polarized waves are generated in the slot plate 51 and radiated from the dielectric window 41 to the processing container 30.

A raw material gas supply structure 60 having, for example, a substantially flat plate shape, is installed between the placing table 31 in the processing container 30 and the radial line slot antenna 42. The raw material gas supply structure 60 has a circular external appearance in a plan view, of which the diameter is at least larger than the diameter of the glass substrate G. The inside of the processing container 30 is divided into a plasma generation region R1 at the radial line slot antenna 42 side and a raw material gas dissociation region R2 at the placing table 31 side by the raw material gas supply structure 60. The raw material gas supply structure 60 may be formed of, for example, alumina. In this case, alumina is a ceramic material and thus has higher heat resistance or strength than a metal material such as, for example, aluminum. In addition, sufficient ion irradiation to the glass substrate may be attained since the plasma generated in the plasma generation region R1 is not trapped in any case. In addition, through the sufficient ion irradiation to a film on the glass substrate, a dense film may be formed. The raw material gas supply structure 60 is also resistant to the nitrogen trifluoride gas for use in dry cleaning. In addition, in order to improve the resistance to nitrogen trifluoride gas, the alumina surface of the raw material gas supply structure 60 may be coated with yttria, spinel, or aluminum nitride.

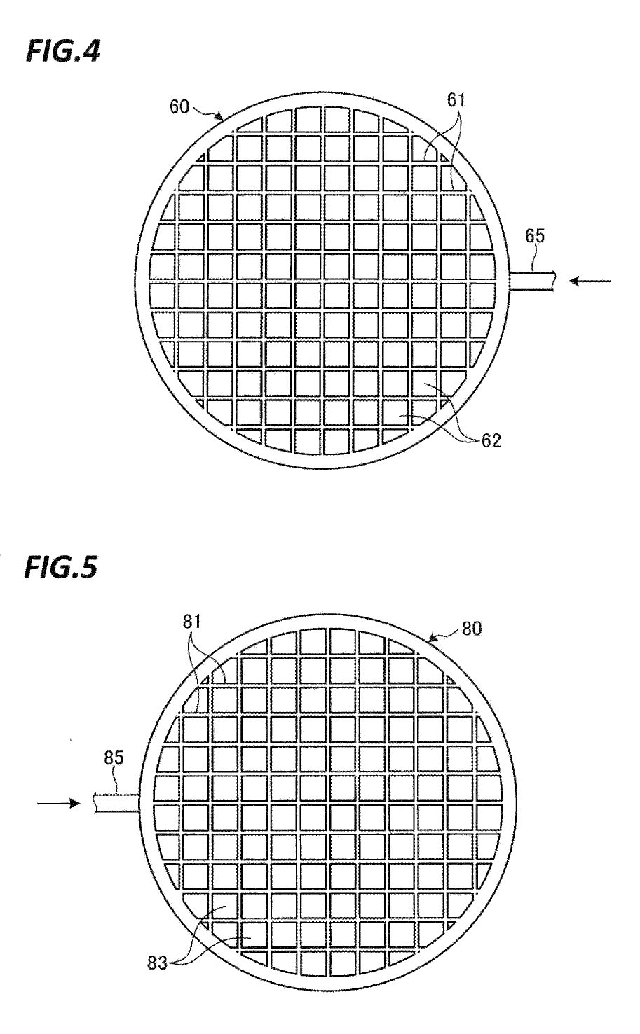

As illustrated in FIG. 4, the raw material gas supply structure 60 is constituted with a series of raw material gas supply pipes 61 which are arranged substantially in a lattice form on the same plane. The raw material gas supply pipes 61 have a rectangular vertical cross section when viewed in an axial direction. A plurality of openings 62 is formed in the gaps between the raw material gas supply pipes 61. Plasma generated in the plasma generation region R1 above the raw material gas supply structure 60 may be introduced into the raw material gas dissociation region R2 at the placing table 31 side, through the openings 62.

A plurality of raw material gas supply ports 63 is formed on the bottom surfaces of the raw material gas supply pipes 61 of the raw material gas supply structure 60 as illustrated in FIG. 3. The raw material gas supply ports 63 are uniformly distributed in the plane of the raw material gas supply structure 60. A gas pipe 65 is connected to the raw material gas supply pipes 61, in which the gas pipe 65 is in communication with a raw material gas supply source 64 provided in the outside of the processing container 30. Raw material gases, for example, a silane-based gas such as, for example, silane (SiH₄) gas and hydrogen (H₂) gas are individually enclosed in the raw material gas supply source 64. A valve 66 and a mass flow controller 67 are provided in the gas pipe 65. With this configuration, a predetermined flow rate of each of the silane gas and hydrogen gas is introduced to the raw material gas supply pipes 61 from the raw material gas supply source 64 through the gas pipe 65. The silane gas and hydrogen gas are supplied from each of the raw material gas supply ports 63 to the raw material gas dissociation region R2 below the raw material gas supply ports 63.

A first plasma excitation gas supply port 70 is formed on the inner circumferential surface of the processing container 30 covering the outer circumference of the plasma generation region R1 to supply a plasma excitation gas that is a raw material of plasma. A plurality of first plasma excitation gas supply ports 70 is formed at multiple locations, for example, along the inner circumferential surface of the processing container 30. The first plasma excitation gas supply ports 70 are connected to, for example, a first plasma excitation gas supply pipe 72 which penetrates the sidewall of the processing container 30 and is in communication with a first plasma excitation gas supply source 71 provided in the outside of the processing container 30. A valve 73 and a mass flow controller 74 are provided in the first plasma excitation gas supply pipe 72. With this configuration, the plasma excitation gas may be supplied to the plasma generation region R1 in the processing container 30 at a predetermined flow rate from a lateral side. In the present exemplary embodiment, for example, argon (Ar) gas is enclosed as the plasma excitation gas in the first plasma excitation gas supply source 71.

For example, a plasma excitation gas supply structure 80, which is substantially flat and has the same configuration as the raw material gas supply structure 60, is laminated on the top surface of the raw material gas supply structure 60. The plasma excitation gas supply structure 80 is constituted with second plasma excitation gas supply pipes 81 arranged in a lattice form as illustrated in FIG. 5. In addition, the plasma excitation gas supply structure 80 is formed of, for example, alumina. Here as elsewhere, alumina is a ceramic material as described above, and thus, has higher heat resistance or strength than a metal material such as, for example, aluminum. In addition, sufficient ion radiation to the glass substrate may be attained since the plasma generated in the plasma generation region R1 is not trapped in any case. In addition, through the sufficient ion radiation to a film on the glass substrate, a dense film may be formed. The plasma excitation gas supply structure 80 is also resistant to the nitrogen trifluoride gas for use in dry cleaning. In addition, in order to improve the resistance to the nitrogen trifluoride gas, the alumina surface of the plasma excitation gas supply structure 80 may be coated with yttria or spinel.

A plurality of second plasma excitation gas supply ports 82 is formed on the top surfaces of the second plasma excitation gas supply pipes 81 as illustrated in FIG. 3. The second plasma excitation gas supply ports 82 are uniformly distributed in the plane of the plasma excitation gas supply structure 80. As a result, the plasma excitation gas may be supplied upwardly from the bottom of the plasma generation region R1. In addition, in the present exemplary embodiment, the plasma excitation gas is, for example, argon gas. In addition to the argon gas, nitrogen (N₂) gas as a raw material gas is supplied from the plasma excitation gas supply structure 80 to the plasma generation region R1.

A plurality of openings 83 is formed in the gaps between the second plasma excitation gas supply pipes 81 arranged in the lattice form, and the plasma generated in the plasma generation region R1 may be injected to the raw material gas dissociation region R2 below the plasma generation region R1 through the plasma excitation gas supply structure 80 and the raw material gas supply structure 60.

A gas pipe 85 is connected to the second plasma excitation gas supply pipes 81, in which the gas pipe 85 is in communication with a second plasma excitation gas supply source 84 provided in the outside of the processing container 30. For example, argon gas serving as a plasma excitation gas and nitrogen gas serving as a raw material gas are individually enclosed in the second plasma excitation gas supply source 84. A valve 86 and a mass flow controller 87 are provided in the gas pipe 85. With this configuration, a predetermined flow rate of each of the nitrogen gas and argon gas may be supplied to the plasma generation region R1 from the second plasma excitation gas supply ports 82.

In addition, the raw material gases and the plasma excitation gases described above correspond to processing gases in the present exemplary embodiment. In addition, the raw material gas supply structure 60 and the plasma excitation gas supply structure 80 correspond to processing gas supply units of the present exemplary embodiment.

Exhaust ports 90 are formed in the bottom of the processing container 30 at opposite lateral sides of the placing table 31 to evacuate the processing container 30. The exhaust ports 90 are connected with an exhaust pipe 92 which is in communication with an exhaust apparatus 91 such as, for example, a turbo molecular pump. By the evacuation from the exhaust ports 90, the inside of the processing container 30 may be maintained at a predetermined pressure, for example, in a range of 10 Pa to 60 Pa as described below.

The plasma film forming apparatus 16 described above is provided with a control unit 100. The control unit 100 is, for example, a computer including a program storage unit (not illustrated). A program for controlling a film forming process of the SiN film 23 on the glass substrate G in the plasma film forming apparatus 16 is stored in the program storage unit. In addition, the program storage unit stores a program for controlling, for example, the supply of a raw material gas, the supply of a plasma excitation gas, the radiation of microwaves, and the operation of a drive system as described above, so as to implement a film forming process in the plasma film forming apparatus 16. In addition, the program storage unit stores a program for controlling an application timing of a bias electric field which is applied by the high frequency power source 35. In addition, the programs may be recorded in a computer readable memory medium such as, for example, a computer readable head disc (HD), a flexible disc (FD), a compact disc (CD), a magneto optical disc (MO), and a memory card, and may be installed to the controller 100 from the memory medium. The supply of a raw material gas, the supply of a plasma excitation gas, the radiation of microwaves, and the application timing of the bias electric field will be described later.

Next, descriptions will be made on a method for forming the SiN film 23, which is performed in the plasma film forming apparatus 16 configured as described above.

First, for example, when the plasma film forming apparatus 16 is started, the supply flow rate of argon gas is adjusted. Specifically, the supply flow rate of argon gas supplied from the first plasma excitation gas supply ports 70 and the supply flow rate of argon gas supplied from the second plasma excitation gas supply ports 82 are adjusted such that the concentration of argon gas supplied to the plasma generation region R1 becomes uniform. In this adjustment of supply flow rate, the argon gas is supplied at an appropriately set supply flow rate from the respective plasma excitation gas supply ports 70 and 82, for example, in a state where the exhaust apparatuses 91 are operated to form the same airflow as in a real film forming process in the processing container 30. In addition, film formation is practically performed on a test substrate at the set supply flow rate, and it is inspected whether the film formation is uniformly performed in the plane of the substrate. The film formation in the plane of the substrate is uniformly performed when the concentration of the argon gas is uniform in the plasma generation region R1. Thus, when it is determined through the inspection that the film formation in the plane of the substrate is not uniformly performed, the setting of the supply flow rates of argon gas from the respective plasma excitation gas supply ports is changed and the film formation is performed again on a test substrate. This process is repeated to set the supply flow rate from each of the plasma excitation gas supply ports 70 and 82 so that the film formation in the plane of the substrate is uniformly performed and hence the concentration of argon gas in the plasma generation region R1 becomes uniform.

After the supply flow rates of argon gas from the respective plasma excitation gas supply ports 70 and 82 are set, a film forming process of a glass substrate G is initiated in the plasma film forming apparatus 16. First, the glass substrate G is carried into the processing container 30 and then attracted to and held on the placing table 31. At this time, the temperature of the glass substrate G is maintained at 100° C. or less, for example, in a range of 50° C. to 100° C. Subsequently, evacuation of the inside of the processing container 30 is stated by the exhaust apparatuses 91 so as to decompress the processing container 30 to a predetermined pressure, for example, in a range of 10 Pa to 60 Pa and to maintain the decompressed state. The temperature of the glass substrate G is not limited to 100° C. or less and may be any temperature so long as an organic EL device A is damaged. The temperature of the glass substrate G may be determined based on, for example, a material of the organic EL device A.

Here, it has been found that when the pressure of the inside of the processing container 30 is below 20 Pa, the SiN film 23 may not be appropriately formed on the glass substrate G. In addition, it has been found that when the pressure within the processing container 30 exceeds 60 Pa, the reaction between gas molecules in a gas phase may be increased to generate particles. For this reason, as described above, the pressure within the processing container 30 is maintained within the range of 10 Pa to 60 Pa.

When the inside of the processing container 30 is decompressed, argon gas is supplied to the plasma generation region R1 from the first plasma excitation gas supply ports 70 at the lateral side and nitrogen gas and argon gas are supplied upwardly to the plasma generation region R1 from the second plasma excitation gas supply ports 82. At this time, the concentration of argon gas in the plasma generation region R1 is uniformly maintained in the plasma generation region. In addition, the nitrogen gas is supplied at the flow rate of 21 sccm, for example. Microwaves having a power of 2.5 W/cm² to 4.7 W/cm² are radiated at a frequency of 2.45 GHz, for example, from the radial line slot antenna 42 to the plasma generation region R1 immediately below the radial line slot antenna 42. Through the radiation of microwaves, the argon gas is turned into plasma and the nitrogen gas is radicalized (ionized) in the plasma generation region R1. At this time, the downwardly progressing microwaves are absorbed to the generated plasma. As a result, high-density plasma is generated in the plasma generation region R1.

The plasma generated in the plasma generation region R1 is injected downwardly into the raw material gas dissociation region R2 through the plasma excitation gas supply structure 80 and the raw material gas supply structure 60. Silane gas and hydrogen gas are supplied to the raw material gas dissociation region R2 from each of the raw material gas supply ports 63 of the raw material gas supply structure 60. At this time, the silane gas is supplied at a flow rate of, for example, 18 sccm and the hydrogen gas is supplied at a flow rate of for example 64 sccm. In addition, the supply flow rate of hydrogen gas is set based on the film characteristics of the SiN film 23 as described below. Each of the silane gas and hydrogen gas is disassociated by plasma introduced from the upper side. Then, the SiN film 23 is deposited on the glass substrate G by the radicals of silane gas and hydrogen gas as well as the radicals of nitrogen gas supplied from the plasma generation region R1.

During or after the formation of the SiN film 23, as illustrated in FIG. 2(c), the plasma film forming apparatus 16 forms a second SiN film 23 of the SiN film 23 by intermittently performing an ON/OFF control of the high frequency power source 35 to apply a bias electric field to a part of the SiN film 23.

Thereafter, when the formation of the SiN film 23 is progressed to form the SiN film 23 having a predetermined thickness on the glass substrate G, the radiation of microwaves or the supply of the processing gases is stopped. Thereafter, the glass substrate G is carried out from the processing container 30 and a series of plasma film forming processes are terminated.

As described above, according to the present exemplary embodiment, the ions in the plasma are drawn into the second SiN film 23-2 by applying a bias electric field to the second SiN film 23-2 which is a part of the SiN film 23 during or after the formation of the SiN film 23. The ions drawn into the second SiN film 23-2 apply ion shock to the second SiN film 23-2 to grow the second SiN film 23-2 in a deposition direction different from that of the first SiN film 23-1 and to grow the pinholes generated in the second SiN film 23-2 in a nonlinear shape. Accordingly, according to the present exemplary embodiment, for example, when moisture infiltrates from the outside, the moisture may be captured (trapped) by the nonlinearly grown pinholes, which may suppress the moisture, which has infiltrated from the outside, from infiltrating into an organic EL device. As a result, according to the present exemplary embodiment, the sealing performance of the SiN film serving as a sealing film may be improved.

Here, it has been found that the controllability of film characteristics of the SiN film 23 may be improved when a processing gas including silane gas, nitrogen gas, and hydrogen gas is used to form a SiN film 23 on the glass substrate G by the above-described plasma film forming process.

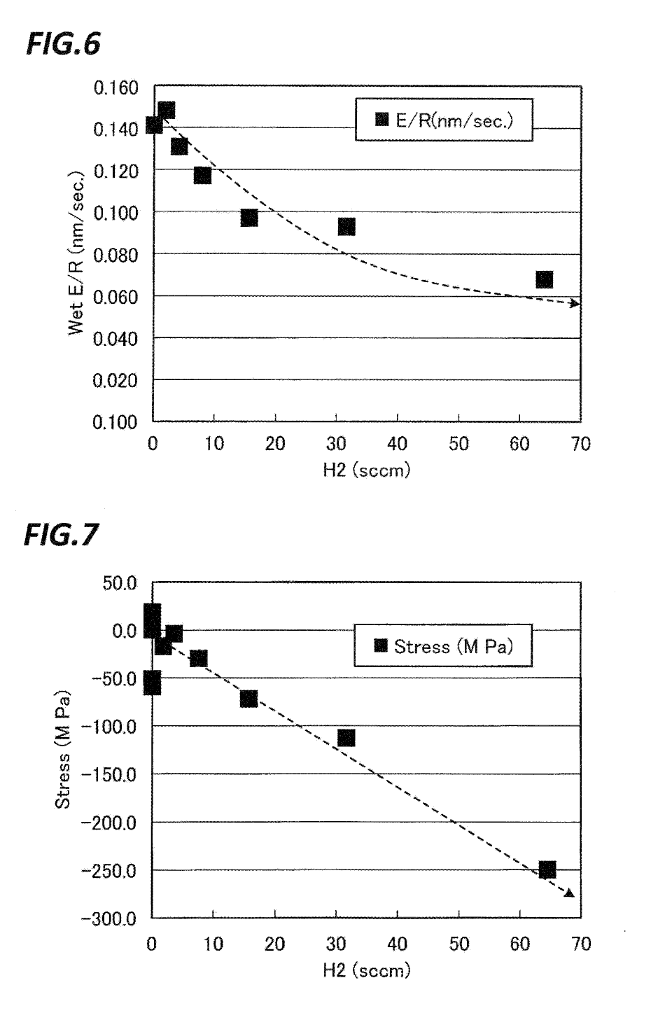

FIG. 6 is a graph illustrating variation in a wet etch rate of a SiN film 23 with respect to hydrofluoric acid, when the supply flow rate of hydrogen gas in the processing gas was varied using the plasma film forming method of the present exemplary embodiment. At this time, the supply flow rate of silane gas was 18 sccm and the supply flow rate of nitrogen gas was 21 sccm. In addition, the temperature of the glass substrate G was 100° C. during the plasma film forming process.

Referring to FIG. 6, it has been found that the wet etch rate of the SiN film 23 is reduced when hydrogen gas is added to the processing gas including silane gas and nitrogen gas. Accordingly, the density of the SiN film 23 is improved and the film quality (chemical resistance and denseness) of the SiN film 23 is improved by the hydrogen gas in the processing gas. In addition, the step coverage of the SiN film 23 is improved. In addition, it has been found that the refraction index of the SiN film 23 is also improved to, for example, 2.0±0.1. Accordingly, by controlling the supply flow rate of hydrogen gas, the wet etch rate of the SiN film 23 may be controlled and the film characteristics of the SiN film 23 may be controlled.

FIG. 7 is a graph illustrating variation in film stress of the SiN film 23 when the supply flow rate of hydrogen gas in the processing gas was varied using the plasma film forming method of the present exemplary embodiment. At this time, the supply flow rate of silane gas was 18 sccm and the supply flow rate of nitrogen gas was 21 sccm. In addition, the temperature of the glass substrate G was 100° C. during the plasma film forming process.

Referring to FIG. 7, it has been found that the film stress of the SiN film 23 is varied to a minus range (compression range) when hydrogen gas is added to the processing gas including silane gas and nitrogen gas. Accordingly, the film stress of the SiN film 23 may be controlled by controlling the supply flow rate of hydrogen gas.

As described above, according to the present exemplary embodiment, the film characteristics of the SiN film 23 may be varied by varying the flow rate of hydrogen gas in the processing gas. Accordingly, the organic EL device A may be appropriately manufactured since the SiN film 23 may be appropriately formed as a sealing film on the organic EL device A. When the SiN film is used as a sealing film, the stress magnitude of the sealing film may have a small absolute value.

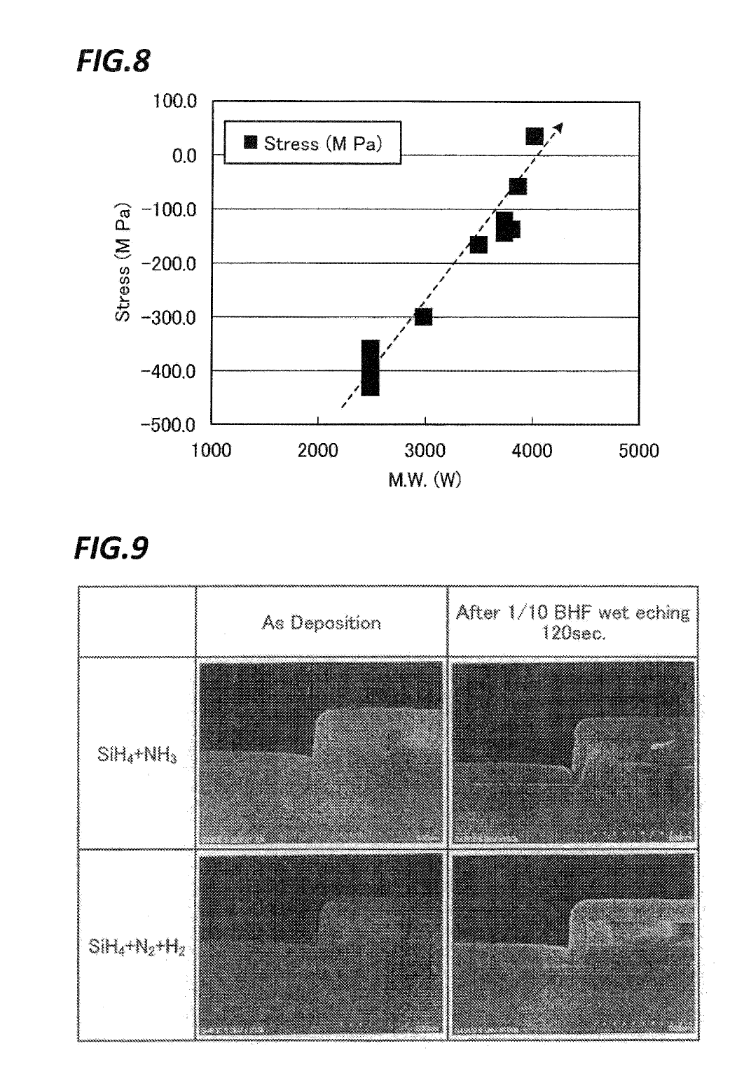

In addition, according to the plasma film forming method of the present exemplary embodiment, plasma is generated using microwaves radiated from the radial line slot antenna 42. Here, it has been found that the power of microwaves and the film stress of the SiN film 23 are approximately proportional to each other as illustrated in FIG. 8 when the processing gas includes silane gas, nitrogen gas, and hydrogen gas. Accordingly, according to the present exemplary embodiment, the film stress of the SiN film 23 may be controlled by controlling the power of microwaves. By optimizing the flow rate of hydrogen gas and the power of microwaves, desired film characteristics may be accurately attained. Specifically, the flow rate of hydrogen gas may be optimized and, thereafter, the power of microwaves may be optimized.

In the related art, formation of a silicon nitride film on a glass substrate using a processing gas including silane gas and ammonia gas (NH₃) as described above has also been performed. However, under a low temperature environment in which the temperature of the glass substrate is 100° C. or less, the ammonia gas supplied prior to forming the silicon nitride film corrodes a metal electrode, for example, an aluminum electrode formed on the base of the silicon nitride film. In addition, unreacted ammonia is trapped in the silicon nitride film since the film is formed under a low temperature environment. Once the ammonia is trapped in the silicon nitride film, the ammonia may be degassed from the silicon nitride film after an environmental test is performed, and thus, the organic EL device may deteriorate.

Whereas, the present exemplary embodiment uses nitrogen gas, instead of ammonia gas. Accordingly, the corrosion of the metal electrode or the deterioration of the organic EL device as described above may be prevented.

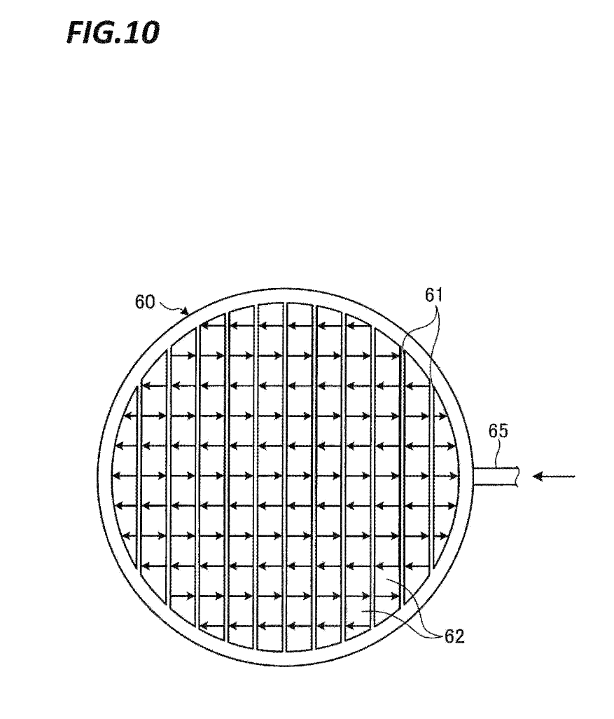

When nitrogen gas is used instead of ammonia gas and hydrogen gas is added to the processing gas as in the present exemplary embodiment, the film characteristics of a formed silicon nitride film may be improved as illustrated in FIG. 9. That is, the film quality (density) of the silicon nitride film at a stepped portion may be improved. In FIG. 9, the upper row represents appearances of a silicon nitride film when a processing gas including silane gas and ammonia gas was used, and the lower row represents appearances of a silicon nitride film when a processing gas including silane gas, nitrogen gas and hydrogen gas was used. In addition, in FIG. 9, the left column represents the appearances of the silicon nitride films immediately after formation thereof, and the right column represents the appearances of the silicon nitride films after wet etching was performed for 120 seconds by buffered hydrofluoric (BHF) acid.

In the plasma film forming apparatus 16 of the present exemplary embodiment, silane gas and hydrogen gas are supplied from the raw material gas supply structure 60 and nitrogen gas and argon gas are supplied from the plasma excitation gas supply structure 80. However, the hydrogen gas may be supplied from the plasma excitation gas supply structure 80. Alternatively, the hydrogen gas may be supplied from both the raw material gas supply structure 60 and the plasma excitation gas supply structure 80. In addition, the argon gas may be supplied from the raw material gas supply structure 60. Alternatively, the argon gas may be supplied from both the raw material gas supply structure 60 and the plasma excitation gas supply structure 80. In any case, the film characteristics of the SiN film 23 may be controlled by controlling the supply flow rate of hydrogen gas as described above.

Here, it has been found that the refraction index of the SiN film 23 is about 2.0 when the SiN film 23 is dense, in particular, when the SiN film 23 has the greatest Si—N coupling density. In addition, it has been found that the refraction index may be 2.0±0.1 in terms of the barrier characteristic (sealing characteristic) of the SiN film 23.

Accordingly, in order to achieve the aforementioned refraction index of 2.0±0.1, in the plasma film forming apparatus 16, the ratio of the supply flow rate of nitrogen gas in relation to the supply flow rate of silane gas may be in a range of 1 to 1.5. Whereas, when a silicon nitride film is formed using silane gas and nitrogen gas in a conventional plasma CVD apparatus, the ratio of the supply flow rate of nitrogen gas in relation to the supply flow rate of silane gas is generally in a range of 10 to 50. Since the conventional plasma CVD apparatus requires a great amount of nitrogen gas as described above, the flow rate of silane gas should be increased and at the same time, the flow rate of nitrogen gas should also be increased to be suitable for the increase of the flow rate of the silane gas in order to increase the film formation rate. Consequently, the exhaust system reaches the limit. For this reason, under the condition of a high film formation rate, it is difficult to maintain the silicon nitride film in the aforementioned refraction index range of 2.0±0.1. Therefore, the plasma film forming apparatus 16 of the present exemplary embodiment exhibits considerably superior effects as compared to the conventional plasma CVD apparatus.

In addition, the film stress of the SiN film 23 may be controlled within the refraction index range of 2.0±0.1 by controlling the ratio of the supply flow rate of nitrogen gas in relation to the supply flow rate of silane gas. Specifically, the film stress may be close to zero. In addition, the film stress may be controlled by adjusting the power of microwaves from the radial line slot antenna 42 or the supply flow rate of hydrogen gas.

The plasma film forming apparatus 16 is capable of facilitating activation of the supplied nitrogen gas, and increasing the dissociation degree of the nitrogen degree. Thus, the plasma film forming apparatus 16 is capable of supplying the nitrogen gas at a low flow rate as compared to the conventional plasma CVD apparatus, as described above. That is, when the nitrogen gas is supplied from the plasma excitation gas supply structure 80, the nitrogen gas is discharged at a relatively high pressure to the plasma generation region R1 in the processing container 30 from the second plasma excitation gas supply ports 82 of the plasma excitation gas supply structure 80 since the plasma excitation supply structure 80 is located sufficiently close to the dielectric window 41 where plasma is generated. Thus, the nitrogen gas is easily ionized to produce a great amount of active nitrogen radicals, for example. As described above, the plasma excitation gas supply structure 80 is located at a position within a distance of 30 mm from the radial line slot antenna 42 (strictly speaking, the dielectric window 41) in order to increase the dissociation degree of nitrogen gas. According to the inventors' research, when the plasma excitation gas supply structure 80 is located at the above-described position, the plasma excitation gas supply structure 80 itself is located in the plasma generation region R1. For this reason, the dissociation degree of nitrogen gas may be increased.

In the plasma film forming apparatus 16 of the present exemplary embodiment, the supply of a raw material gas may be performed simultaneously with or before the generation of plasma. That is, silane gas and hydrogen gas (or silane gas alone) are first supplied from the raw material gas supply structure 60. Simultaneously with or after the supply of silane gas and hydrogen gas, argon gas and nitrogen gas (and hydrogen gas) are supplied from the plasma excitation gas supply structure 80 and microwaves are radiated from the radial line slot antenna 42. Then, plasma is generated in the plasma generation region R1.

Here, the cathode layer 22 including a metal element is formed on the glass substrate G on which the SiN film 23 will be formed. For example, when the organic EL device A including the cathode layer 22 is exposed to plasma, the cathode layer 22 may be peeled off from the light emitting layer 21, and the organic EL device A may be damaged. Whereas, in the present exemplary embodiment, the formation of the SiN film 23 is initiated simultaneously with the generation of plasma because the plasma is generated simultaneously with or after the supply of silane gas and hydrogen gas. Accordingly, the surface of the cathode layer 22 may be protected so that the organic EL device A may be appropriately manufactured without being exposed to the plasma.

In the present exemplary embodiment, the raw material gas supply ports 63 are formed to be directed downward from the raw material gas supply structure 60 and the second plasma excitation gas supply ports 82 are formed to be directed upward from the plasma excitation gas supply structure 80. However, the raw material gas supply ports 63 and the second plasma excitation gas supply ports 82 may be formed in an inclined direction other than the horizontal direction or the vertically downward direction. For example, the raw material gas supply ports 63 and the second plasma excitation gas supply ports may be formed toward a direction inclined by 45 degrees from the horizontal direction.

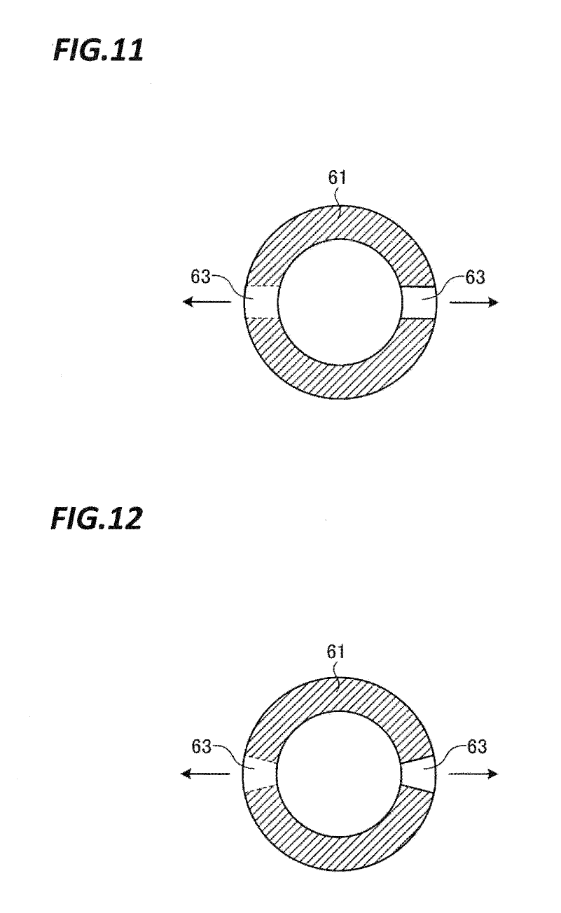

In this case, as illustrated in FIG. 10, the raw material gas supply structure 60 is formed with a plurality of raw material gas supply pipes 61 that is elongated in parallel to one another. The raw material gas supply pipes 61 are equidistantly arranged in the raw material gas supply structure 60. Each of the raw material gas supply pipes 61 includes raw material gas supply ports 63 formed on both lateral sides thereof to supply a raw material gas in the horizontal direction, as illustrated in FIG. 11. The raw material gas supply ports 63 are equidistantly arranged in each of the raw material gas supply pipes 61, as illustrated in FIG. 10. In addition, neighboring raw material gas supply ports 63 are formed to be oppositely directed in the horizontal direction. In addition, the plasma excitation gas supply structure 80 may have the same configuration as the raw material gas supply structure 60. The raw material gas supply structure 60 and the plasma excitation gas supply structure 80 are arranged such that the raw material gas supply pipes 61 of the raw material gas supply structure 60 and the second plasma excitation gas supply pipes 81 of the plasma excitation gas supply structure 80 are arranged approximately in a lattice form.

The raw material gas supplied from the raw material gas supply ports 63 is mainly silicon nitride and is deposited in the raw material gas supply ports 63. Therefore, the deposited silicon nitride is removed by dry cleaning during maintenance. In this case, when the raw material gas supply ports 63 are formed to be directed downward, it is difficult for plasma to enter the raw material gas supply ports. Thus, the silicon nitride deposited in the raw material gas supply ports 63 may not be completely removed from the inside of the raw material gas supply ports 63. In this regard, when the raw material gas supply ports 63 are horizontally oriented as in the present exemplary embodiment, the generated plasma enters the raw material gas supply ports 63 to the inside of the raw material gas supply ports 63 during the dry cleaning. Therefore, the silicon nitride may be completely removed even from the inside of the raw material gas supply ports 63. Accordingly, after the maintenance, the raw material gas may be appropriately supplied from the raw material gas supply ports 63 and the silicon nitride film 23 may be more appropriately formed.

In addition, the raw material gas supply structure 60 and the plasma excitation gas supply structure 80 are arranged such that the raw material gas supply pipes 61 of the raw material gas supply structure 60 and the second plasma excitation gas supply pipes 81 of the plasma excitation gas supply structure 80 are arranged approximately in a lattice form. Therefore, the raw material gas supply structure 60 and the plasma excitation gas supply structure 80 may be more easily manufactured than manufacturing each of the raw material gas supply structure 60 and the plasma excitation gas supply structure 80 approximately in a lattice form. In addition, the raw material gas supply structure 60 and the plasma excitation gas supply structure 80 may allow the plasma generated in the plasma generation region R1 to easily pass therethrough, as well.

Each of the raw material gas supply ports 63 may be formed such that its inner diameter is gradually enlarged from the inside toward the outside in a tapered form, as illustrated in FIG. 12. In this case, plasma may more easily enter the plasma gas supply ports 63 during the dry cleaning. Accordingly, the silicon nitride deposited in the raw material gas supply ports 63 may be more surely removed. Likewise, each of the second plasma excitation gas supply ports 82 may be formed such that its inner diameter is enlarged from the inside toward the outside in a tapered form.

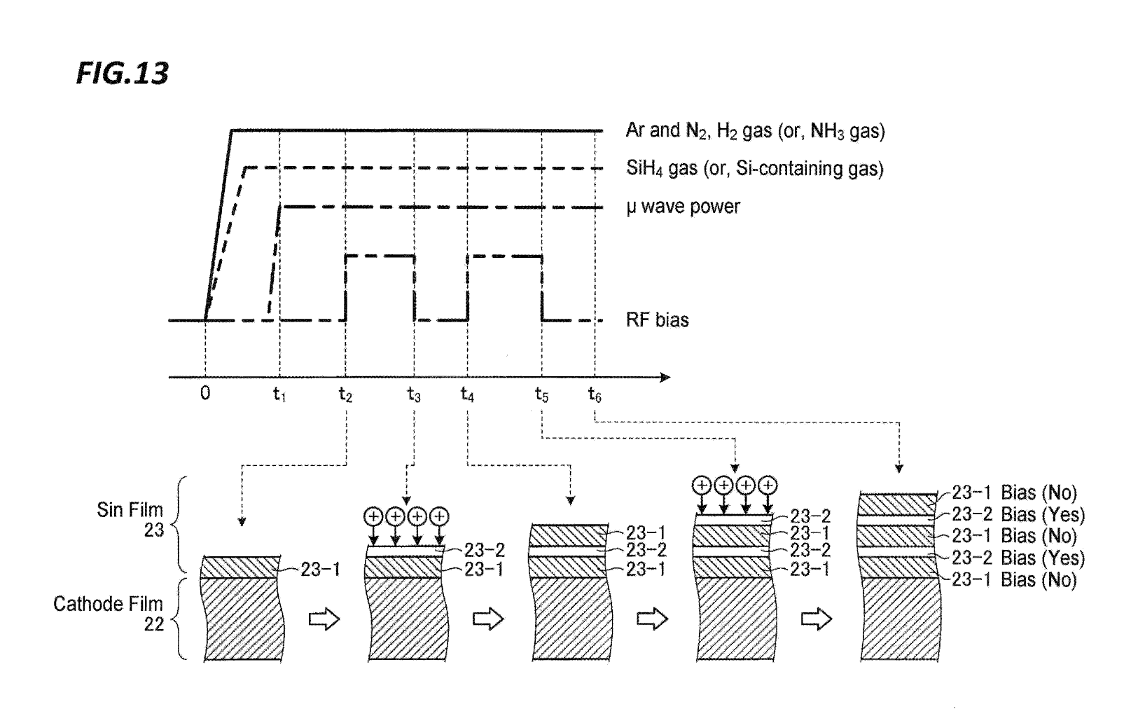

Next, descriptions will be made on a first film forming example of the SiN film 23 formed by the plasma film forming apparatus 16 of the present exemplary embodiment. FIG. 13 is a time chart of respective conditions in a first film forming example of the SiN film and a view illustrating film forming states at respective timings.

The control unit 100 of the plasma film forming apparatus 16 controls the supply of a raw material gas, the supply of a plasma excitation gas, the radiation of microwaves, and the application timing of a bias electric field based on the time chart in the upper part of FIG. 13 during the formation of the SiN film 23. Specifically, first, the control unit 100 initiates the supply of argon (Ar) gas, nitrogen (N₂) gas, hydrogen (H₂) gas, silane (SiN₄) gas, and the power of microwaves (μ waves) at a certain time 0. The control unit 100 may supply ammonia (NH₃) gas instead of the nitrogen gas and the hydrogen gas. In addition, the control unit 100 may supply another Si containing gas instead of the silane gas.

At a time t₁ after a lapse of a predetermined time from the input of argon gas, nitrogen gas, hydrogen gas and silane gas, and slightly delayed microwave power, the supply of gases and the supply of microwave power are stabilized. In addition, at a time t₂ after a lapse of a predetermined time, a first SiN film 23-1 is laminated on the cathode layer 22 of the organic EL device, as illustrated in the lower part of FIG. 13. The first SiN film 23-1 laminated during the period from the time t₁ to the time t₂ has a thickness of about 30 nm to about 100 nm, for example.

Subsequently, as illustrated in the upper part of FIG. 13, the control unit 100 applies a bias electric field (high frequency bias) using the high frequency power source 35 during the period from the time t₂ to a time t₃ while continuously supplying the argon gas, nitrogen gas, hydrogen gas, silane gas, and microwave power.

In this way, when the bias electric field is applied during the formation of the SiN film 23, ions in the plasma are drawn into the SiN film 23 as illustrated in the lower part of FIG. 13. As a result, a second SiN film 23-2 is formed on the first SiN film 23-1 in a deposition direction different from that of the first SiN film 23-1. The second SiN film 23-2 laminated during a period from the time t₂ to the time t₃ has a thickness of about 10 nm to about 50 nm, for example.

Subsequently, as illustrated in the upper part of FIG. 13, the control unit 100 stops the application of the bias electric field during a period from the time t₃ to a time t₄ while continuously supplying the argon gas, nitrogen gas, hydrogen gas, silane gas, and microwave power.

At the time t₄ after a lapse of a predetermined time, another first SiN film 23-1 is laminated on the second SiN film 23-2, as illustrated in the lower part of FIG. 13. The first SiN film 23-1 laminated during the period from the time t₃ to the time t₄ has a thickness of about 30 nm to about 100 nm, for example.

Subsequently, as illustrated in the upper part of FIG. 13, the control unit 100 applies a bias electric field (high frequency bias) using the high frequency power source 35 during a period from the time t₄ to a time t₅ while continuously supplying the argon gas, nitrogen gas, hydrogen gas, silane gas, and microwave power.

In this way, when the bias electric field is applied during the formation of the SiN film 23, ions in the plasma are drawn into the SiN film 23, as illustrated in the lower part of FIG. 13. As a result, another second SiN film 23-2 is formed on the first SiN film 23-1 in a deposition direction different from that of the first SiN film 23-1. The second SiN film 23-2 laminated during the period from the time t₄ to the time t₅ has a thickness of about 10 nm to about 50 nm, for example.

Subsequently, as illustrated in the upper part of FIG. 13, the control unit 100 stops the application of the bias electric field during a period from the time t₅ to a time t₆ while continuously supplying the argon gas, nitrogen gas, hydrogen gas, silane gas, and microwave power.

At the time t₆, as illustrated in the lower part of FIG. 13, another first SiN film 23-1 is laminated on the second SiN film 23-2. The first SiN film 23-1 laminated during the period from the time t₅ to the time t₆ has a thickness of about 30 nm to about 100 nm, for example.

According to the first film forming example, the second SiN films 23-2 of the SiN film 23 may be formed by intermittently applying the bias electric field using the high frequency power source 35 during the formation of the SiN film 23. The second SiN films 23-2 have a deposition direction different from that of the first SiN films 23-1. Thus, for example, even if pinholes are generated in the SiN film 23, the second SiN films 23-2 may cause the generated pinholes to be grown in a nonlinear shape (e.g., a zigzag shape). The nonlinearly grown pinholes efficiently capture (trap) moisture, for example, when the moisture infiltrates from the outside, thereby preventing the moisture from reaching the organic EL device. As a result, according to the first film forming example, the sealing performance of the SiN film serving as a sealing film may be improved because the moisture, which has infiltrated from the outside, may be suppressed from infiltrating into the organic EL device.

In addition, according to the first film forming example, the first SiN films 23-1 and the second SiN films 23-2 may be alternately laminated in multiple layers through a simplified control of intermittently applying a bias electric field during the formation of the SiN film 23. Accordingly, in the first film forming example, by the simplified control, the deterioration of throughput of the SiN film serving as a sealing film may be suppressed and further, the sealing performance of the SiN film may be improved.

In addition, according to the first film forming example, a first SiN film 23-1 is formed as the lowermost layer of the SiN film 23. In other words, according to the first film forming example, the intermittent ON/OFF control of the bias electric field during the formation of the SiN film 23 starts from OFF of the bias electric field. In this way, according to the first film forming example, the first SiN film 23-1, to which no bias electric field is applied, may be used as a film to be in contact with the cathode layer 22 of the organic EL device. As a result, in the first film forming example, by starting the intermittent ON/OFF control of the bias electric field from OFF of the bias electric field, the organic EL device may be protected from being damaged due to the draw-in of ions into the organic EL device.

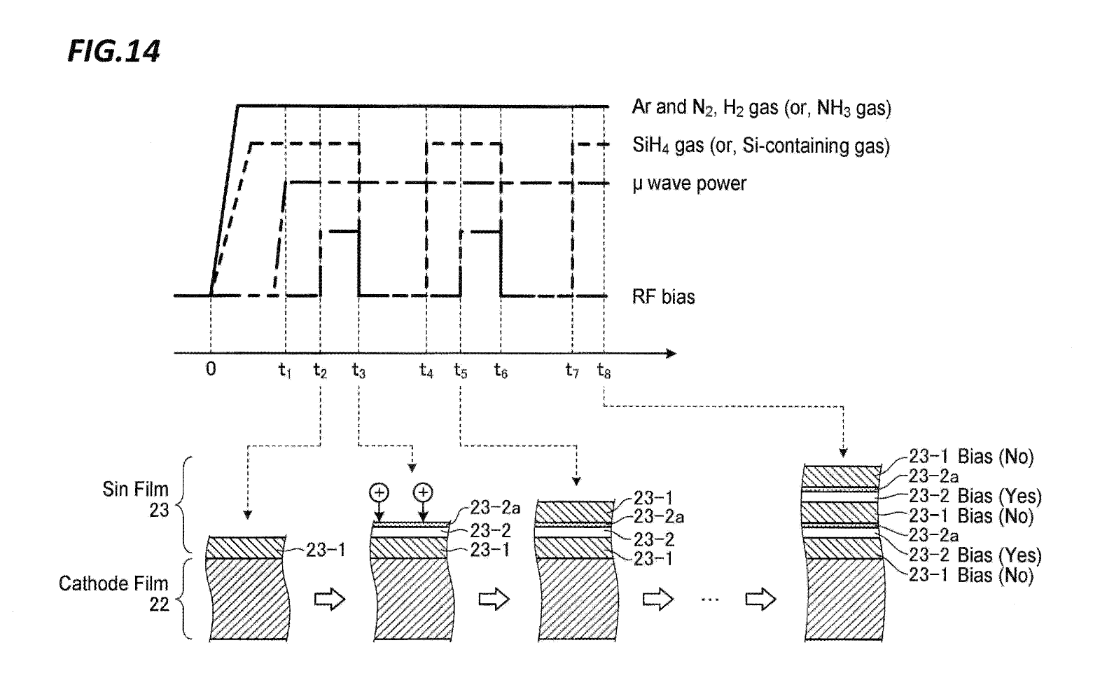

Next, descriptions will be made on a second film forming example of the SiN film 23 formed by the plasma film forming apparatus 16 of the present exemplary embodiment. FIG. 14 is a time chart of respective conditions in a second film forming example of the SiN film and a view illustrating film forming states at respective timings.

The first film forming example successively performs the supply of raw material gases and applies the bias electric field by intermittently performing the ON/OFF control of the high frequency power source during the formation of the SiN film 23 in which the raw material gases are supplied. Whereas, the second film forming example intermittently performs the supply of raw material gases and applies a bias electric field by performing the ON control of the high frequency power source during the formation of the SiN film 23 in which the raw material gases are supplied, and performing the OFF control of the high frequency power source at a timing of stopping the supply of the raw material gas. The second film forming example is different from the first film forming example in terms of the supply of the raw material gases and the ON/OFF control of the bias electric field, for example.

The control unit 100 of the plasma film forming apparatus 16 controls the supply of a raw material gas, the supply of a plasma excitation gas, the radiation of microwaves, and the application timing of a bias electric field based on the time chart in the upper part of FIG. 14 during the formation of the SiN film 23. In addition, the control unit 100 intermittently performs the supply of silane gas among raw material gases when the SiN film 23 is formed. Then, the control unit 100 applies a bias electric field by performing the ON control of the high frequency power source 35 during the formation of the SiN film 23 in which the supply of silane gas is performed and performing the OFF control of the high frequency power source 35 to be turned OFF at a timing of stopping the supply of silane gas. Specifically, first, the control unit 100 initiates the supply of argon (Ar) gas, nitrogen (N₂) gas, hydrogen (H₂) gas, silane (SiN₄) gas, and the power of microwaves (μ waves) at a certain time 0. The control unit 100 may supply ammonia (NH₃) gas instead of the nitrogen gas and the hydrogen gas. In addition, the control unit 100 may supply another Si containing gas instead of the silane gas.

At a time t₁ after a lapse of a predetermined time from the input of argon gas, nitrogen gas, hydrogen gas, and silane gas and slightly delayed microwave power, the supply of gases and the supply of microwave power are stabilized. In addition, at a time t₂ after a lapse of a predetermined time, a first SiN film 23-1 is laminated on the cathode layer 22 of the organic EL device as illustrated in the lower part of FIG. 14. The first SiN film 23-1 laminated during the period from the time t₁ to the time t₂ has a thickness of about 30 nm to about 100 nm, for example.

Subsequently, as illustrated in the upper part of FIG. 14, the control unit 100 applies a bias electric field using the high frequency power source 35 during a period from the time t₂ to a time t₃ while continuously supplying the argon gas, nitrogen gas, hydrogen gas, silane gas, and slightly delayed microwave power. In addition, the control unit 100 stops the supply of silane gas at the time t₃ and stops the application of the bias electric field at the time t₃ of stopping the supply of silane gas.

In this way, when the bias electric field is applied during the formation of the SiN film 23 in which the supply of silane gas is performed and the application of the bias electric field is stopped simultaneously with stopping the supply of silane gas, ions in the plasma are drawn into the SiN film 23 as illustrated in the lower part of FIG. 14. More specifically, ions in the plasma of argon gas, nitrogen gas, hydrogen gas and silane gas are drawn into the SiN film 23 during the formation of the SiN film 23 in which the supply of silane gas is performed, and ions in the plasma of argon gas, nitrogen gas, and hydrogen gas are drawn into the SiN film 23 when the supply of silane gas is stopped. As a result, a second SiN film 23-2 is formed on the first SiN film 23-1 in a deposition direction different from that of the first SiN film 23-1, and a second SiN film 23-2a having a greater progress degree of nitrification than the second SiN film 23-2 is formed on the surface of the second SiN film 23-2. The second SiN films 23-2 and 23-2a laminated during the period from the time t₂ to the time t₃ have a thickness of about 5 nm to about 20 nm, for example.

Subsequently, as illustrated in the upper part of FIG. 14, the control unit 100 stops the application of the bias electric field during a period from the time t₃ to a time t₅ and restarts the supply of silane gas at the time t₄.

At the time t₅, as illustrated in the lower part of FIG. 14, another first SiN film 23-1 is laminated on the second SiN film 23-2a. The first SiN film 23-1 laminated during the period from the time t₄ to the time t₅ has a thickness of about 30 nm to about 100 nm, for example.

Subsequently, as illustrated in the upper part of FIG. 14, the control unit 100 applies a bias electric field using the high frequency power source 35 during a period from the time t₅ to a time t₆ while continuously supplying the argon gas, nitrogen gas, hydrogen gas, silane gas, and microwave power. In addition, the control unit 100 stops the supply of silane gas at the time t₆ and stops the application of the bias electric field at the time t₆ of stopping the supply of silane gas.

In this way, when the bias electric field is applied during the formation of the SiN film 23 in which the supply of silane gas is performed and the application of the bias electric field is stopped simultaneously with stopping the supply of silane gas, ions in the plasma are drawn into the SiN film 23. More specifically, ions in the plasma of argon gas, nitrogen gas, hydrogen gas, and silane gas are drawn into the SiN film 23 during the formation of the SiN film 23 in which the supply of silane gas is performed, and ions in the plasma of argon gas, nitrogen gas, and hydrogen gas are drawn into the SiN film 23 when the supply of silane gas is stopped. As a result, another second SiN film 23-2 is formed on the first SiN film 23-1 in a deposition direction different from that of the first SiN film 23-1, and another second SiN film 23-2a having a greater progress degree of nitrification than the second SiN film 23-2 is formed on the surface of the second SiN film 23-2. The second SiN films 23-2 and 23-2a laminated during the period from the time t₅ to the time t₆ have a thickness of about 5 nm to about 20 nm, for example.

Subsequently, as illustrated in the upper part of FIG. 14, the control unit 100 stops the application of the bias electric field during a period from the time t₆ to a time t₈ and restarts the supply of silane gas at a time t₇.

At the time t₈, as illustrated in the lower part of FIG. 14, another first SiN film 23-1 is laminated on the second SiN film 23-2a. The first SiN film 23-1 laminated during the period from the time t₇ to the time t₈ has a thickness of about 30 nm to about 100 nm, for example.

According to the second film forming example, in the same manner as the first film forming example, the second SiN films 23-2 of the SiN film 23 may be formed by intermittently applying the bias electric field using the high frequency power source 35 during the formation of the SiN film 23. Since the second SiN films 23-2 have a deposition direction different from that of the first SiN films 23-1, for example, even if pinholes are generated in the SiN film 23, the second SiN films 23-2 may cause the generated pinholes to be grown in a nonlinear shape (e.g., a zigzag shape). The nonlinearly grown pinholes efficiently capture (trap) moisture, for example, when the moisture infiltrates from the outside. As a result, according to the second film forming example, the sealing performance of the SiN film serving as a sealing film may be improved because the moisture, which has infiltrated from the outside, may be suppressed from infiltrating into the organic EL device.

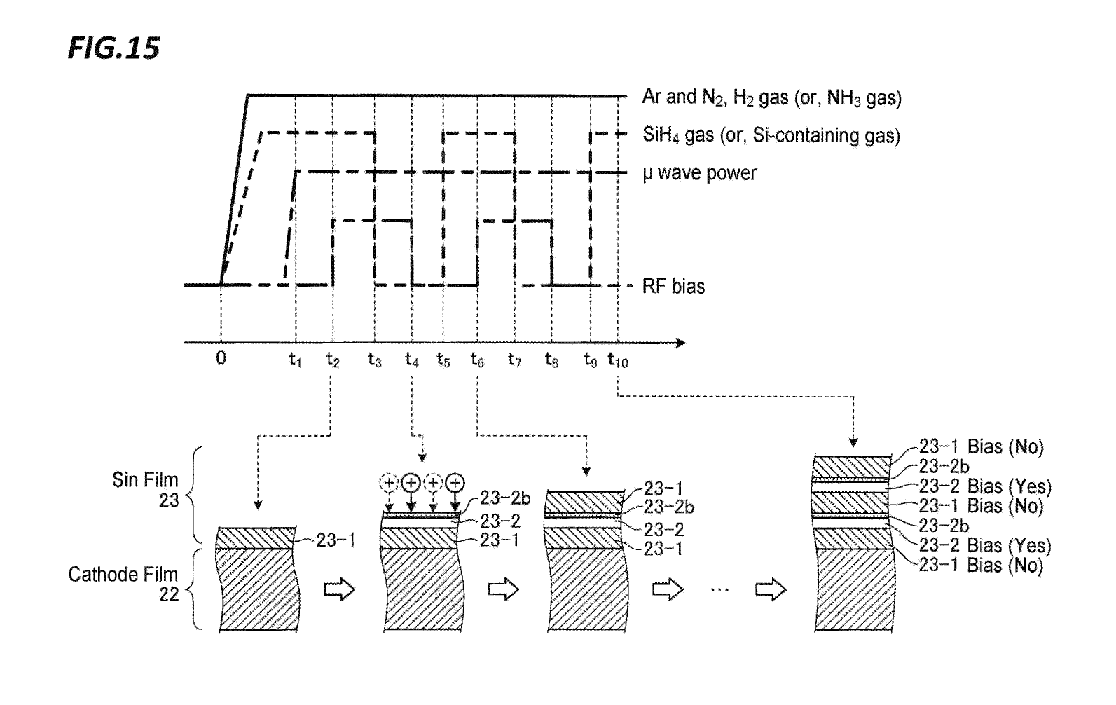

Next, descriptions will be made on a third film forming example of the SiN film 23 formed by the plasma film forming apparatus 16 of the present exemplary embodiment. FIG. 15 is a time chart of respective conditions in a third film forming example of the SiN film and a view illustrating film forming states at respective timings.

The first film forming example successively performs the supply of raw material gases and applies a bias electric field by intermittently performing an ON/OFF control of the high frequency power source during the formation of the SiN film 23 in which raw material gases are supplied. Whereas, the third film forming example intermittently performs the supply of raw material gases, and applies the bias electric field by performing the ON control of the high frequency power source during the formation of the SiN film 23 in which the raw material gas is supplied and performing the OFF control of the high frequency power source at a timing different from a timing of stopping the supply of the raw material gases. The third film forming example is different from the first film forming example in terms of the supply of raw material gases and the ON/OFF control of the bias electric field, for example.

During the formation of the SiN film 23, the control unit 100 of the plasma film forming apparatus 16 controls the supply of a raw material gas, the supply of a plasma excitation gas, the radiation of microwaves, and the application timing of a bias electric field according to the time chart in the upper part of FIG. 15. In addition, the control unit 100 intermittently performs the supply of silane gas among raw material gases while the SiN film 23 is formed. Then, the control unit 100 applies the bias electric field by performing the ON control of the high frequency power source 35 during the formation of the SiN film 23 in which the supply of silane gas is performed and performing the OFF control of the high frequency power source 35 during a predetermined period from a timing of stopping the supply of silane gas to a timing of restarting the supply of silane gas. Specifically, first, the control unit 100 initiates the supply of argon (Ar) gas, nitrogen (N₂) gas, hydrogen (H₂) gas, silane (SiN₄) gas, and power of microwaves (μ waves) at a certain time 0. The control unit 100 may supply ammonia (NH₃) gas instead of the nitrogen gas and the hydrogen gas. In addition, the control unit 100 may supply another Si containing gas instead of the silane gas.

At a time t₁ after a lapse of a predetermined time from the input of argon gas, nitrogen gas, hydrogen gas, and silane gas, and slightly delayed microwave power, the supply of gases and the supply of microwave power are stabilized. In addition, at a time t₂ after a lapse of a predetermined time, a first SiN film 23-1 is laminated on the cathode layer 22 of the organic EL device as illustrated in the lower part of FIG. 15. The first SiN film 23-1 laminated during the period from the time t₁ to the time t₂ has a thickness of about 30 nm to about 100 nm, for example.

Subsequently, as illustrated in the upper part of FIG. 15, the control unit 100 applies a bias electric field using the high frequency power source 35 during a period from the time t₂ to a time t₃ while continuously supplying the argon gas, nitrogen gas, hydrogen gas, and silane gas, and slightly delayed microwave power. In addition, the control unit 100 stops the supply of silane gas at the time t₃ and applies the bias electric field using the high frequency power source 35 during a period from the time t₃ to a time t₄ while the supply of silane gas is stopped. In addition, the control unit 100 stops the application of the bias electric field at the time t₄ during the period from the time t₃ of stopping the supply of silane gas to a time t₅ of restarting the supply of silane gas.

In this way, when the bias electric field is applied during the formation of the SiN film 23 and during a predetermined period after the formation of the SiN film 23 and the application of the bias electric field is stopped prior to restarting the supply of silane gas, ions in the plasma are drawn into the SiN film 23 as illustrated in the lower part of FIG. 15. More specifically, ions in the plasma of argon gas, nitrogen gas, hydrogen gas and silane gas are drawn into the SiN film 23 during the formation of the SiN film 23 in which the supply of silane gas is performed. Meanwhile, ions in the plasma of argon gas, nitrogen gas, and hydrogen gas are drawn into the SiN film 23 during a predetermined period after the formation of the SiN film 23 in which the supply of silane gas is stopped. As a result, a second SiN film 23-2 is formed on the first SiN film 23-1 in a deposition direction different from that of the first SiN film 23-1, and a second SiN film 23-2b having a greater progress degree of nitrification than the second SiN film 23-2 is formed on the surface of the second SiN film 23-2. The second SiN films 23-2 and 23-2b laminated during the period from the time t₂ to the time t₄ have a thickness of about 10 nm to about 50 nm, for example.

Subsequently, as illustrated in the upper part of FIG. 15, the control unit 100 stops the application of the bias electric field during a period from the time t₄ to a time t₆ and restarts the supply of silane gas at the time t₅.

At the time t₆, as illustrated in the lower part of FIG. 15, another first SiN film 23-1 is laminated on the second SiN film 23-2a. The first SiN film 23-1 laminated during the period from the time t₅ to the time t₆ has a thickness of about 30 nm to about 100 nm, for example.

Subsequently, as illustrated in the upper part of FIG. 15, the control unit 100 applies the bias electric field using the high frequency power source 35 during a period from the time t₆ to a time t₇ while continuously supplying the argon gas, nitrogen gas, hydrogen gas, silane gas, and microwave power. In addition, the control unit 100 stops the supply of silane gas at the time t₇ and applies the bias electric field using the high frequency power source 35 during the period from the time t₇ to the time t₈ while the supply of silane gas is stopped. In addition, the control unit 100 stops the application of the bias electric field at the time t₈ during the period from the time t₇ of stopping the supply of silane gas to the time t₉ of restarting the supply of silane gas.

In this way, when the bias electric field is applied during the formation of the SiN film 23 and during a predetermined period after the formation of the SiN film 23 and the application of the bias electric field is stopped prior to restarting the supply of silane gas, ions in the plasma are drawn into the SiN film 23. More specifically, ions in the plasma of argon gas, nitrogen gas, hydrogen gas, and silane gas are drawn into the SiN film 23 during the formation of the SiN film 23 in which the supply of silane gas is performed. Meanwhile, ions in the plasma of argon gas, nitrogen gas, and hydrogen gas are drawn into the SiN film 23 during a predetermined period after the formation of the SiN film 23 in which the supply of silane gas is stopped. As a result, another second SiN film 23-2 is formed on the first SiN film 23-1 in a deposition direction different from that of the first SiN film 23-1, and another second SiN film 23-2b having a greater progress degree of nitrification than the second SiN film 23-2 is formed on the surface of the second SiN film 23-2. The second SiN films 23-2 and 23-2b laminated during the period from the time t₆ to the time t₈ have a thickness of about 10 nm to about 50 nm, for example.

Subsequently, as illustrated in the upper part of FIG. 15, the control unit 100 stops the application of the bias electric field during a period from the time t₈ to a time t₁₀ and restarts the supply of silane gas at the time t₉.

At the time t₁₀, as illustrated in the lower part of FIG. 15, another first SiN film 23-1 is laminated on the second SiN film 23-2b. The first SiN film 23-1 laminated during the period from the time t₉ to the time t₁₀ has a thickness of about 30 nm to about 100 nm, for example.

According to the third film forming example, the second SiN films 23-2 of the SiN film 23 may be formed by intermittently applying the bias electric field using the high frequency power source 35 during formation of the SiN film 23, as the first film forming example. Since the second SiN films 23-2 have a deposition direction different from that of the first SiN films 23-1, the second SiN films 23-2 may cause the generated pinholes to be grown in a nonlinear shape (e.g., a zigzag shape), for example, even if pinholes are generated in the SiN film 23. For example, when the moisture infiltrates from the outside, the moisture is efficiently captured (trapped) and does not reach the organic EL device because the generated pinholes have a nonlinear shape (e.g., a zigzag shape) and paths thereof are long. As a result, according to the third film forming example, the sealing performance of the SiN film serving as a sealing film may be improved because the moisture, which has infiltrated from the outside, may be suppressed from infiltrating into the organic EL device.

In addition, according to the third film forming example, silane gas is intermittently supplied and the bias electric field is applied by performing the ON control of the high frequency power source 35 during the formation of the SiN film 23 in which the supply of silane gas is performed and performing the OFF control of the high frequency power source 35 during a predetermined period from a timing of stopping the supply of silane gas to a timing of restarting the supply of silane gas. As a result, the second SiN films 23-2b having a greater process degree of nitrification than the second SiN films 23-2 may be formed on the surfaces of the second SiN films 23-2. Thus, according to the third film forming example, the second SiN films 23-2b serving as an interface between the second SiN films 23-2 and the first SiN films 23-1 may be hardened, which may increase the coating efficiency of a stepped portion of the SiN film 23 (step coverage). As a result, according to the third film forming example, the sealing performance of the SiN film serving as a sealing film may be further improved. In addition, according to the third film forming example, the bias electric field is applied during a predetermined duration after the formation of the SiN film 23 in which the supply of silane gas is stopped. Thus, a state in which ions in non-film formation plasma are drawn into the SiN film 23 may be prolonged and the nitrification of the second SiN films 23-2b may be facilitated.

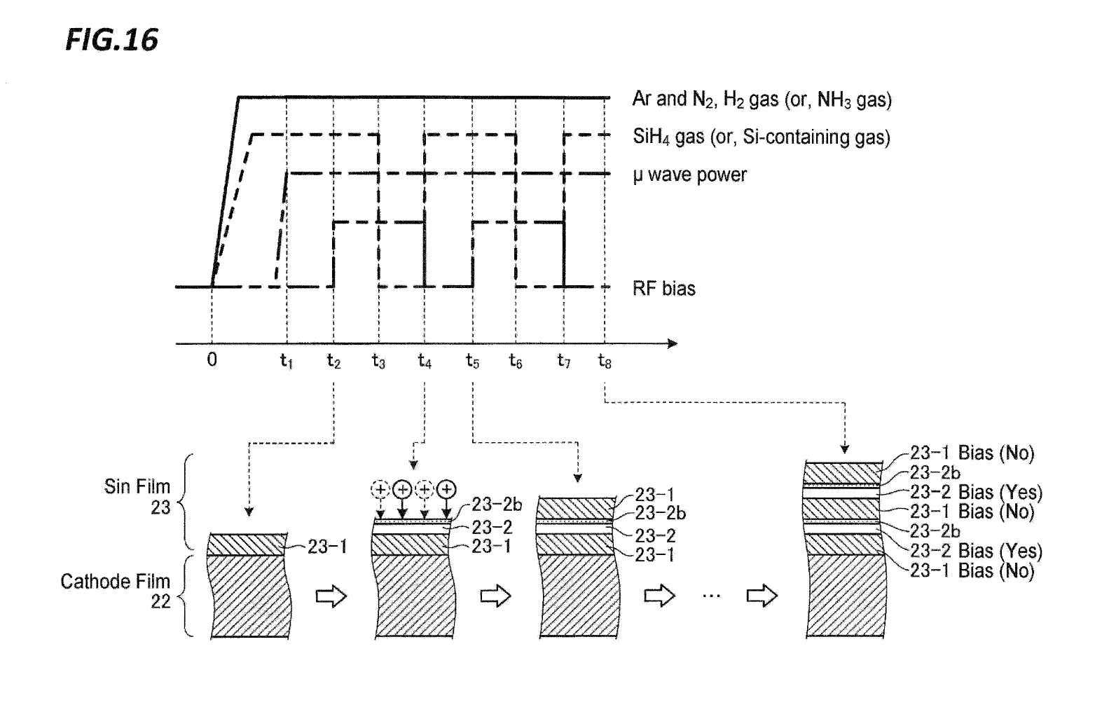

Next, descriptions will be made on a fourth film forming example of the SiN film 23 formed by the plasma film forming apparatus 16 of the present exemplary embodiment. FIG. 16 is a time chart of respective conditions in a fourth film forming example of the SiN film and a view illustrating film forming states at respective timings.

The fourth film forming example is different from the third film forming example in terms of an OFF control timing of the high frequency power source.

The control unit 100 of the plasma film forming apparatus 16 controls the supply of a raw material gas, the supply of a plasma excitation gas, the radiation of microwaves, and the application timing of a bias electric field based on the time chart in the upper part of FIG. 16 during the formation of the SiN film 23. In addition, the control unit 100 intermittently performs the supply of silane gas among raw material gases while the SiN film 23 is formed. Then, the control unit 100 applies the bias electric field by performing the ON control of the high frequency power source 35 during the formation of the SiN film 23 in which the supply of silane gas is performed and performing the OFF control of the high frequency power source 35 at a timing of restarting the supply of silane gas. Specifically, first, the control unit 100 initiates the supply of argon (Ar) gas, nitrogen (N₂) gas, hydrogen (H₂) gas, silane (SiN₄) gas, and power of microwaves (μ waves) at a time 0. The control unit 100 may supply ammonia (NH₃) gas instead of the nitrogen gas and the hydrogen gas. In addition, the control unit 100 may supply another Si containing gas instead of the silane gas.

At a time t₁ after a lapse of a predetermined time from the input of argon gas, nitrogen gas, hydrogen gas, and silane gas, and slightly delayed microwave power, the supply of gases and the supply of microwave power are stabilized. In addition, at a time t₂ after a lapse of a predetermined time a first SiN film 23-1 is laminated on the cathode layer 22 of the organic EL device, as illustrated in the lower part of FIG. 16. The first SiN film 23-1 laminated during the period from the time t₁ to the time t₂ has a thickness of about 30 nm to about 100 nm, for example.

Subsequently, as illustrated in the upper part of FIG. 16, the control unit 100 applies a bias electric field using the high frequency power source 35 during a period from the time t₂ to a time t₃ while continuously supplying the argon gas, nitrogen gas, hydrogen gas, and silane gas, and slightly delayed microwave power. In addition, the control unit 100 stops the supply of silane gas at the time t₃ and applies a bias electric field using the high frequency power source 35 during the period from the time t₃ to the time t₄ while the supply of silane gas is stopped. In addition, the control unit 100 stops the application of the bias electric field at the time t₄ of restarting the supply of silane gas is restarted.

In this way, when the bias electric field is applied during the formation of the SiN film 23 and during a predetermined period after the formation of the SiN film 23 and the application of the bias electric field is stopped at the time of restarting the supply of silane gas, ions in the plasma are drawn into the SiN film 23, as illustrated in the lower part of FIG. 16. More specifically, ions in the plasma of argon gas, nitrogen gas, hydrogen gas, and silane gas are drawn into the SiN film 23 during the formation of the SiN film 23 in which the supply of silane gas is performed. Meanwhile, ions in the plasma of argon gas, nitrogen gas, and hydrogen gas are drawn into the SiN film 23 during a predetermined period after the formation of the SiN film 23 in which the supply of silane gas is stopped. As a result, a second SiN film 23-2 is formed on the first SiN film 23-1 in a deposition direction different from the first SiN film 23-1, and a second SiN film 23-2b having a greater progress degree of nitrification than the second SiN film 23-2 is formed on the surface of the second SiN film 23-2. The second SiN films 23-2 and 23-2b laminated during the period from the time t₂ to the time t₄ have a thickness of about 10 nm to about 50 nm, for example.

Subsequently, as illustrated in the upper part of FIG. 16, the control unit 100 stops the application of the bias electric field during a period from the time t₄ to a time t₅ and restarts the supply of silane gas at the time t₄.

At the time t₅, as illustrated in the lower part of FIG. 16, the first SiN film 23-1 is laminated on the second SiN film 23-2b. The first SiN film 23-1 laminated during the period from the time t₄ to the time t₅ has a thickness of about 30 nm to about 100 nm, for example.

Subsequently, as illustrated in the upper part of FIG. 16, the control unit 100 applies the bias electric field using the high frequency power source 35 during a period from the time t₅ to a time t₆ while continuously supplying the argon gas, nitrogen gas, hydrogen gas, silane gas, and microwave power. In addition, the control unit 100 stops the supply of silane gas at the time t₆ and applies the bias electric field using the high frequency power source 35 during the period from the time t₆ to the time t₇ while the supply of silane gas is stopped. In addition, the control unit 100 stops the application of the bias electric field at the time t₇ of restarting the supply of silane gas.

In this way, when the bias electric field is applied during the formation of the SiN film 23 and during a predetermined duration after the formation of the SiN film 23 in which the supply of silane gas is stopped and the application of the bias electric field is stopped when the supply of silane gas is restarted, ions in the plasma are drawn into the SiN film 23. More specifically, ions in the plasma of argon gas, nitrogen gas, hydrogen gas, and silane gas are drawn into the SiN film 23 during the formation of the SiN film 23 in which the supply of silane gas is performed. Meanwhile, ions in the plasma of argon gas, nitrogen gas, and hydrogen gas are drawn into the SiN film 23 during a predetermined period after the formation of the SiN film 23 in which the supply of silane gas is stopped. As a result, another second SiN film 23-2 is formed on the first SiN film 23-1 in a deposition direction different from the first SiN film 23-1, and another second SiN film 23-2b having a greater progress degree of nitrification than the second SiN film 23-2 is formed on the surface of the second SiN film 23-2. The second SiN films 23-2 and 23-2b laminated during the period from the time t₅ to the time t₇ have a thickness of about 10 nm to about 50 nm, for example.

Subsequently, as illustrated in the upper part of FIG. 16, the control unit 100 stops the application of the bias electric field during a period from the time t₇ to a time t₈ and restarts the supply of silane gas at the time t₇.

At the time t₈, as illustrated in the lower part of FIG. 16, another first SiN film 23-1 is laminated on the second SiN film 23-2b. The first SiN film 23-1 laminated during the period from the time t₇ to the time t₈ has a thickness of about 30 nm to about 100 nm, for example.

According to the fourth film forming example, silane gas is intermittently supplied and the bias electric field is applied by performing the ON control of the high frequency power source 35 during the formation of the SiN film 23 in which the supply of silane gas is performed and performing the OFF control the high frequency power source 35 at the timing of restarting the supply of silane gas. As a result, the second SiN films 23-2b having a greater process degree of nitrification than the second SiN films 23-2 may be formed on the surfaces of the second SiN films 23-2. Thus, according to the fourth film forming example, the second SiN films 23-2b serving as an interface between the second SiN film 23-2s and the first SiN films 23-1 may be hardened, which may increase the coating efficiency of a stepped portion of the SiN film 23 (step coverage). As a result, according to the fourth film forming example, the sealing performance of the SiN film serving as a sealing film may be further improved. In addition, according to the fourth film forming example, the bias electric field is applied until the time of restarting the supply of silane gas after the formation of the SiN film 23 in which the supply of silane gas is stopped. Thus, a state in which ions in the non-film forming plasma are drawn into the SiN film 23 may be prolonged to the maximum extent and the nitrification of the second SiN films 23-2b may be facilitated.

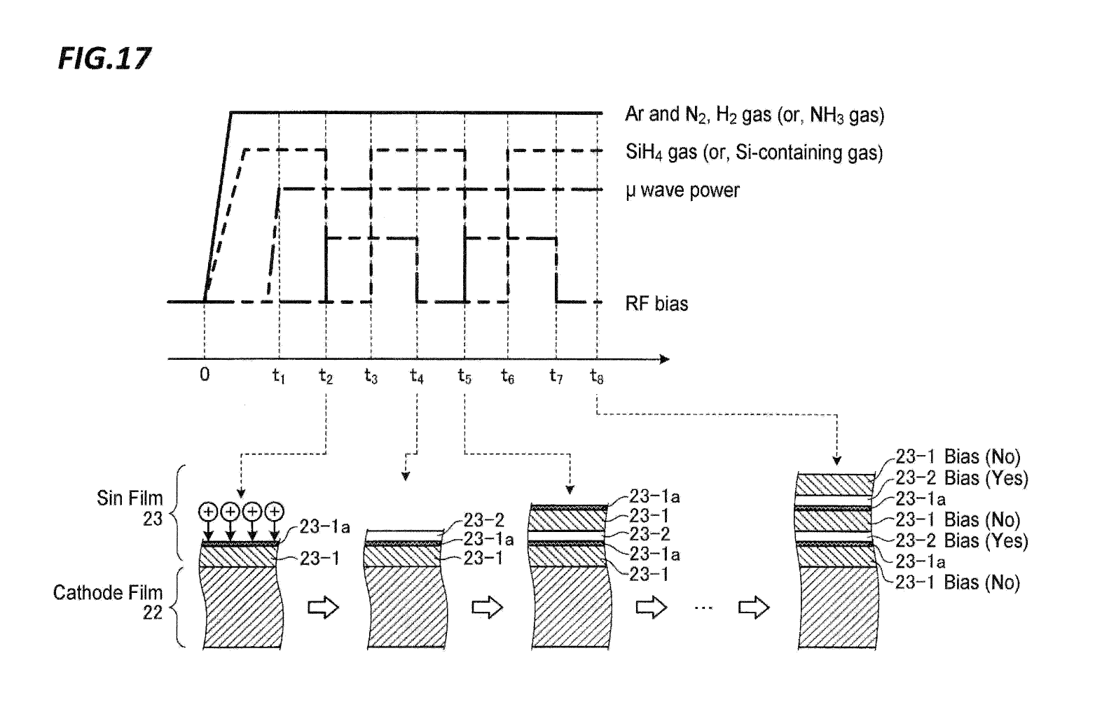

Next, descriptions will be made on a fifth film forming example of the SiN film 23 formed by the plasma film forming apparatus 16 of the present exemplary embodiment. FIG. 17 is a time chart of respective conditions in a fifth film forming example of the SiN film and a view illustrating film forming states at respective timings.

The first film forming example successively performs the supply of raw material gases and applying a bias electric field by intermittently performing the ON/OFF control of the high frequency power source during the formation of the SiN film 23 in which the raw material gases are supplied. Whereas, the fifth film forming example intermittently performs the supply of raw materials and applies the bias electric field by performing the ON control of the high frequency power source at a timing of stopping the supply of the raw material gas and performing the OFF control of the high frequency power source during the formation of the SiN film 23 in which the supply of the raw material gas is performed. The fifth film forming example is different from the first film forming example in terms of the supply of raw material gases and the ON/OFF control of the bias electric field, for example.

The control unit 100 of the plasma film forming apparatus 16 controls the supply of raw material gases, the supply of a plasma excitation gas, the radiation of microwaves, and the application timing of the bias electric field according to the time chart in the upper part of FIG. 17 during the formation of the SiN film 23. In addition, the control unit 100 intermittently performs the supply of silane gas among raw material gases when the SiN film 23 is formed. Then, the control unit 100 applies the bias electric field by performing the ON control of the high frequency power source 35 at a timing of stopping the supply of silane gas and performing the OFF control of the high frequency power source 35 during the formation of the SiN film 23 in which the supply of silane gas is performed. Specifically, first, the control unit 100 initiate the supply of argon (Ar) gas, nitrogen (N₂) gas, hydrogen (H₂) gas, silane (SiN₄) gas, and power of microwaves (μ waves) at a certain time 0. The control unit 100 may supply ammonia (NH₃) gas instead of the nitrogen gas and the hydrogen gas. In addition, the control unit 100 may supply another Si containing gas instead of the silane gas.

At a time t₁ after a lapse of a predetermined time from the input of argon gas, nitrogen gas, hydrogen gas, and silane gas and slightly delayed microwave power, the supply of gases and the supply of microwave power are stabilized.

Subsequently, the control unit 100 stops the supply of silane gas at the time t₂ and performs the ON control of the high frequency power source 35 at the time t₂ of stopping the supply of silane gas.

As described above, when the application of the bias electric field is initiated simultaneously with stopping the supply of silane gas without applying the bias electric field during the formation of the SiN film 23, ions in the plasma are drawn into the SiN film 23 as illustrated in the lower part of FIG. 17. More specifically, ions in the plasma are not drawn into the SiN film 23 during the formation of the SiN film 23 in which the supply of silane gas is performed, and ions in the plasma of argon gas, nitrogen gas, and hydrogen gas are drawn into the SiN film 23 when the supply of silane gas is stopped. As a result, a first SiN film 23-1 is formed on the cathode layer 22 of the organic EL device, and another first SiN film 23-1a having a greater progress degree of nitrification than the first SiN film 23-1 is formed on the surface of the first SiN film 23-1. The first SiN films 23-1 and 23-1a laminated during the period from the time t₁ to the time t₂ have a thickness of about 30 nm to about 100 nm, for example.

Subsequently, as illustrated in the upper part of FIG. 17, the control unit 100 applies a bias electric field using the high frequency power source 35 during a period from the time t₂ to a time t₃ in a state where the supply of silane gas is stopped. In addition, the control unit 100 restarts the supply of silane gas at a time t₄. In addition, the control unit 100 applies the bias electric field using the high frequency power source 35 during the period from the time t₃ to the time t₄ in a state in which the argon gas, nitrogen gas, hydrogen gas, silane gas and microwave power are continuously supplied.

At the time t₄, as illustrated in the lower part of FIG. 17, a second SiN film 23-2 is laminated on the first SiN film 23-1a. The second SiN film 23-2 laminated during the period from the time t₂ to the time t₄ has a thickness of about 10 nm to about 50 nm, for example.

Subsequently, the control unit 100 stops the supply of silane gas at a time t₅ and applies the bias electric field by performing the ON-control of the high frequency power source 35 at the time t₅ of stopping the supply of silane gas.

When the application of the bias electric field is started simultaneously with stopping the supply of silane gas without applying the bias electric field during the formation of the SiN 23 as described above, ions in the plasma are drawn into the SiN film 23 as illustrated in the lower part of FIG. 17. More specifically, ions in the plasma are not drawn into the SiN film 23 during the formation of the SiN film 23 in which the supply of silane gas is performed, and ions in the plasma of argon gas, nitrogen gas, and hydrogen gas are drawn into the SiN film 23 when the supply of silane gas is stopped. As a result, at the time t₅, as illustrated in the lower part of FIG. 17, the first SiN film 23-1 is formed on the cathode layer 22 of the organic EL device, and a first SiN film 23-1a having a greater progress degree of nitrification than the first SiN film 23-1 is formed on the surface of the first SiN film 23-1. The first SiN films 23-1 and 23-1a laminated during the period from the time t₄ to the time t₅ have a thickness of about 30 nm to about 100 nm, for example.

Subsequently, as illustrated in the upper part of FIG. 17, the control unit 100 applies the bias electric field using the high frequency power source 35 during a period from the time t₅ to a time t₆ in a state in which the supply of silane gas is stopped. In addition, the control unit 100 restarts the supply of silane gas at the time t₆. In addition, the control unit 100 applies the bias electric field using the high frequency power source 35 during a period from the time t₆ to a time t₇ in a state in which the argon gas, nitrogen gas, hydrogen gas, silane gas, and microwave power are continuously supplied.

At the time t₇, another second SiN film 23-2 is laminated on the first SiN film 23-1a. The second SiN film 23-2 laminated during the period from the time t₅ to the time t₇ has a thickness of about 10 nm to about 50 nm, for example.

Subsequently, as illustrated in the upper part of FIG. 17, the control unit 100 stops the application of the bias electric field during the period from the time t₇ to the time t₈ in a state in which the argon gas, nitrogen gas, hydrogen gas, silane gas, and microwave power are continuously supplied.

At the time t₈, as illustrated in the lower part of FIG. 17, another first SiN film 23-1 is laminated on the second SiN film 23-2. The first SiN film 23-1 laminated during the period from the time t₇ to the time t₈ has a thickness of about 30 nm to about 100 nm, for example.

According to the fifth film forming example, the second SiN films 23-2 may be formed in the SiN film 23 by intermittently applying the bias electric field using the high frequency power source 35 after the formation of the SiN film 23 as in the first film forming example. The second SiN film 23-2 has a deposition direction different from that of the first SiN film 23-1. Thus, for example, even if pinholes are generated in the SiN film 23, the generated pinholes may be grown in a nonlinear shape (e.g., a zigzag shape). For example, when the moisture infiltrates from the outside, the nonlinearly grown pinholes may efficiently capture (trap) the moisture. As a result, according to the fifth film forming example, the sealing performance of the SiN film serving as a sealing film may be improved because the moisture, which has infiltrated from the outside, may be suppressed from infiltrating into the organic EL device.

In addition, according to the fifth film forming example, silane gas is intermittently supplied and the bias electric field is applied by performing the ON control of the high frequency power source 35 at a timing of stopping the supply of silane gas is stopped and performing the OFF control of the high frequency power source 35 during the formation of the SiN film 23 in which the supply of silane gas is performed. As a result, a first SiN film 23-1a having a greater process degree of nitrification than the first SiN film 23-1 may be formed on the surface of the first SiN film 23-1. In this way, according to the fifth film forming example, the first SiN films 23-1a serving as an interface between the second SiN films 23-2 and the first SiN films 23-1 may be hardened, which may increase the coating efficiency of a stepped portion of the SiN film 23 (step coverage). As a result, according to the fifth film forming example, the sealing performance of the SiN film serving as a sealing film may be further improved.

Although descriptions have been made on the exemplary embodiment in which a processing time for applying a bias electric field to a part of the SiN film 23 is constant has been described in the first film forming example to the fifth film forming example by way of example, the exemplary embodiment is not limited thereto. The processing time for applying a bias electric field to a part of the SiN film 23 may be set to increase as the thickness of the SiN film 23 increases. In this way, in a state where the SiN film 23 has a relatively small thickness, the organic EL device may be prevented from being damaged as ions are drawn into the organic EL device.

As described above, by the plasma film forming apparatus 16 of the present exemplary embodiment, as a bias electric field is applied to the second SiN films 23-2 of the SiN film 23 during or after the formation of the SiN film 23, ions in the plasma are drawn into the second SiN films 23-2. The ions drawn into the second SiN films 23-2 apply ion shock to the second SiN films 23-2, so that the second SiN films 23-2 are grown in a deposition direction different from that of the first SiN films 23-1 and pinholes generated in the second SiN films 23-2 are grown in a nonlinear shape. Accordingly, through the use of the plasma film forming apparatus 16 of the present exemplary embodiment, for example, when moisture infiltrates from the outside, the moisture may be captured (trapped) in the nonlinearly grown pinholes, which may suppress the moisture, which has infiltrated from the outside, from infiltrating into the organic EL device. As a result, according to the present exemplary embodiment, the sealing performance of the SiN film serving as a sealing film may be improved.

In addition, although descriptions have been made on the case where silane gas is used as a silane-based gas in the present exemplary embodiment, the silane-based gas is not limited to the silane gas. It has been found that when, for example, di-silane (Si₂H₆) gas is used, the step coverage of the SiN film 23 may be further improved as compared to the case where silane gas is used.

In addition, although the plasma film forming apparatus 16 of the present exemplary embodiment generates plasma using microwaves from the radial line slot antenna 42, the generation of plasma is not limited to the present exemplary embodiment. For example, capacitively coupled plasma (CCP), inductively coupled plasma (ICP), electron cyclotron resonance plasma (ECRP), and helicon-wave excitation plasma (HWP) may be used as the plasma. In any cases, it is preferable that high density plasma is used because the formation of the SiN film 23 is performed under a low temperature environment in which the temperature of the glass substrate G is 100° C. or less.

In addition, although descriptions have been made on the case where the organic EL device A is manufactured by forming the SiN film 23 as a sealing film on the glass substrate G in the above-described embodiment has described, the present disclosure may be applied to a case where other organic electron devices are manufactured. For example, the method for forming a silicon nitride film according to the present disclosure may be applied to a case where, for example, an organic transistor, an organic solar cell, or an organic field effect transistor (FET) is manufactured as the organic EL device. In addition, the present disclosure may be broadly applied to a case where a silicon nitride film is formed on a substrate under a low temperature environment in which the temperature of the substrate is 100° C. or less, in addition to the manufacture of the organic EL device.

Although the exemplary embodiments of the present disclosure have been described above with reference to the accompanying drawings, the present disclosure is not limited to the exemplary embodiments. It is apparent that various modifications or changes may be conceived by those skilled in the art within the scope of technical ideas defined in the claims. It shall be understood that the modifications or changes belong to the technical scope of the present disclosure.

Hereinafter, the film forming method disclosed herein will be described in detail with reference to examples. However, the film forming method disclosed herein is not limited to the following examples.

### Example 1

In Example 1, a series of film formation processes of placing a substrate in a processing container, supplying a processing gas to the processing container, and performing a plasma processing using plasma of the processing gas was performed. During or after the formation of a SiN film, a bias electric field was applied to a part of the SiN film. Various conditions used in Example 1 are as follows. Example 1 corresponds to the fifth film forming example illustrated in FIG. 17.

Microwave power: 4000 W

Pressure: 21 Pa

Temperature of placing table: 80° C.

Intermittent supply of processing gas: Performed

Processing gas: Ar/N₂/H₂=1450/76/128 sccm, SiH₄=54 sccm (when supplied)

ON/OFF control of high frequency bias (bias electric field): Performed

High frequency bias (bias electric field): 10 W (when performing ON control)

After the series of film formation processes were performed, the vapor transmittance of the SiN film formed on the substrate was measured. In the measurement, a Ca reaction method was used in which a Ca layer is deposited on the SiN film as a measurement target object, and the vapor transmittance is calculated based on moisture having passed through the SiN film and an area of a reaction part of the Ca layer.

### Comparative Example 1

In Comparative Example 1, a series of film formation processes of placing a substrate in a processing container, supplying a processing gas to the processing container, and performing a plasma processing using plasma of the processing gas to form a SiN film on the substrate were performed. In Comparative Example 1, however, the processing gas was successively supplied and no bias electric field was applied, unlike Example 1. Conditions used in Comparative Example 1 are as follows.

Microwave power: 4000 W

Pressure: 21 Pa

Temperature of placing table: 80° C.

Intermittent Supply of processing gas: Not performed

Processing gas: Ar/N₂/H₂/SiH₄=1450/76/128/54 sccm

ON/OFF control of high frequency bias (bias electric field): Not performed

High frequency bias (bias electric field): 0 W (Always OFF control)

In addition, the vapor transmittance of the SiN film formed on the substrate was measured after the series of film formation processes were performed. In the measurement, a Ca reaction method was used in which a Ca layer is deposited on the SiN film as a measurement target object, and the vapor transmittance is calculated based on moisture having passed through the SiN film and an area of a reaction part of the Ca layer.

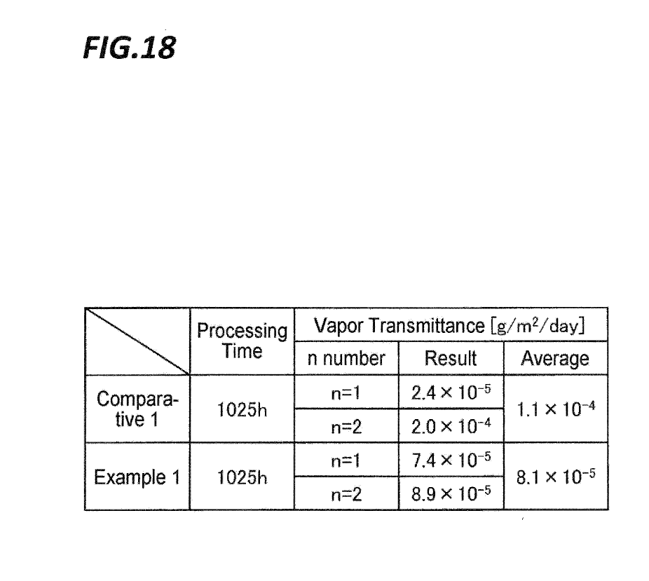

FIG. 18 is a table representing processing results of Comparative Example 1 and Example 1. In FIG. 18, “Processing Time” represents a time required for measurement, “n number” represents the number of times of measurement, “Result” represents measured results, and “Average” represents an average value of vapor transmittances measured n times [g/m²/day].

As illustrated in FIG. 18, in Example 1 in which the bias electric field was applied to a part of a SiN film while intermittently supplying the processing gas has a reduced average value of vapor transmittances of SiN films, as compared to Comparative Example 1 in which no bias electric field was applied while successively supplying the processing gas. In other words, in Example 1, it was possible to improve the sealing performance of the SiN films serving as a sealing film as compared to Comparative Example 1.

### DESCRIPTION OF SYMBOLS

1: substrate processing system, 16: plasma film forming apparatus, 20: anode layer, 21: light emitting layer, 22: cathode layer, 23: silicon nitride film, 30: processing container, 31: placing table, 35, high frequency power source, 42: radial line slot antenna, 60: raw material gas supply structure, 62: opening, 63: raw material gas supply port, 70: first plasma excitation gas supply port, 80: plasma excitation gas supply structure, 82: second plasma excitation gas supply port, 83: opening, 90: exhaust port, 100: control unit, A: organic EL device, G: glass substrate, R1: plasma generation region, R2: raw material gas dissociation region

1. A method for forming a silicon nitride film on a substrate accommodated in a processing container, the method comprising:
supplying a processing gas including a silane-based gas, nitrogen gas, and hydrogen gas or ammonia gas to the processing container;
forming the silicon nitride film on the substrate by exciting the processing gas to generate plasma and performing a plasma processing by the plasma; and
applying a bias electric field to a part of the silicon nitride film by intermittently performing an ON/OFF control of a high frequency power source during or after the forming of the silicon nitride film,
wherein a processing time of applying the bias electric field to a part of the silicon nitride film increases as a film thickness of the silicon nitride film increases.

2. The method according to claim 1, wherein, in the supplying of the processing gas to the processing container, supply of at least the silane-based gas among the gases included in the processing gas is intermittently performed, and
in the applying of the bias electric field to a part of the silicon nitride film, the bias electric field is applied to the part of the silicon nitride film by performing the ON control of the high frequency power source during the forming of the silicon nitride film in which the supply of the silane-based gas is performed and performing the OFF control of the high frequency power source at a timing of stopping the supply of the silane-based gas.

3. The method according to claim 1, wherein, in the supplying of the processing gas to the processing container, supply of at least the silane-based gas among the gases included in the processing gas is intermittently repeated, and
in the applying of the bias electric field to a part of the silicon nitride film, the bias electric field is applied to the part of the silicon nitride film by performing the ON control of the high frequency power source during the forming of the silicon nitride film in which the supply of the silane-based gas is performed and performing the OFF control of the high frequency power source during a predetermined period from at a timing of stopping the supply of the silane-based gas to a timing of restarting the supply of the silane-based gas.

4. The method according to claim 3, wherein, in the applying of the bias electric field to part of the silicon nitride film, the OFF control of the high frequency power source is performed at the timing of restarting the supply of the silane-based gas during the predetermined period.

5. The method according to claim 1, wherein, in the supplying of the processing gas to the processing container, supply of at least the silane-based gas among the gases included in the processing gas is intermittently repeated, and
in the applying of the bias electric field to a part of the silicon nitride film, the bias electric field is applied to the part of the silicon nitride film by performing the ON control of the high frequency power source at a timing of stopping the supply of the silane-based gas and performing the OFF control of the high frequency power source during the forming of the silicon nitride film in which the supply of the silane-based gas is performed.

6-7. (canceled)

8. The method according to claim 1, wherein a pressure within the processing container is maintained in a range of 10 Pa to 60 Pa during the plasma processing using the plasma.

9. The method according to claim 1, wherein a supply flow rate of the hydrogen gas is controlled to control film stress of the silicon nitride film.

10. The method according to claim 1, wherein the plasma is generated as the processing gas is excited by microwaves.

11. The method according to claim 10, wherein a power of the microwaves is controlled to control film stress of the silicon nitride film.

12. The method according to claim 1, wherein the processing gas includes a raw material gas to form the silicon nitride film and a plasma excitation gas to generate the plasma, and
after the processing gas is stabilized to a desired processing condition, supply of a power of the microwaves (μ waves) is initiated to generate the plasma.

13. The method according to claim 1, wherein a ratio of a supply flow rate of the nitrogen gas in relation to a supply flow rate of the silane-based gas in the processing gas to be supplied to the processing container ranges 1 to 1.5.

14-25. (canceled)

26. An apparatus for forming a silicon nitride film on a substrate, the apparatus comprising:
a processing container configured to accommodate and process a substrate;
a processing gas supply unit configured to supply a processing gas including a silane-based gas, nitrogen gas, and hydrogen gas or ammonia gas to the processing container;
a plasma excitation unit configured to excite the processing gas so as to generate plasma;
a high frequency power source configured to apply a bias electric field to the substrate; and
a control unit configured to cause the processing gas supply unit to supply the processing gas including the silane-based gas, nitrogen gas, and hydrogen gas or ammonia gas, to cause the plasma excitation unit to generate plasma by exciting the processing gas so that a silicon nitride film is formed on the substrate by performing a plasma processing by the plasma, and to intermittently performs an ON/OFF control of the high frequency power surface during or after the formation of the silicon nitride film to applying the bias electric field to a part of the silicon nitride film,
wherein a processing time of applying the bias electric field to a part of the silicon nitride film increases as a film thickness of the silicon nitride film increases.

27. The apparatus according to claim 26, wherein the control unit causes the processing gas supply unit to intermittently performs supply of at least the silane-based gas among the gases included in the processing gas, and the control unit performs the ON control of the high frequency power during the forming of the silicon nitride film in which the supply of the silane-based gas is performed and performs the OFF control of the high frequency power source at a timing of stopping the supply of the silane-based gas so that the bias electric field is applied to the part of the silicon nitride film by performing.

28. The apparatus according to claim 26, wherein the control unit causes the processing gas supply unit to perform supply of at least the silane-based gas among the gases included in the processing gas is intermittently repeated, and the control unit performs the ON control of the high frequency power source during the forming of the silicon nitride film in which the supply of the silane-based gas is performed and performs the OFF control of the high frequency power source during a predetermined period from at a timing of stopping the supply of the silane-based gas to a timing of restarting the supply of the silane-based gas so that the bias electric field is applied to the part of the silicon nitride film.

29. The apparatus according to claim 28, wherein the control unit performs the OFF control of the high frequency power source at the timing of restarting the supply of the silane-based gas during the predetermined period.

30. The apparatus according to claim 26, wherein the control unit causes the processing gas supply unit to intermittently perform supply of at least the silane-based gas among the gases included in the processing gas, and the control unit performs the ON control of the high frequency power source at a timing of stopping the supply of the silane-based gas and performs the OFF control of the high frequency power source during the forming of the silicon nitride film in which the supply of the silane-based gas is performed so that the bias electric field is applied to the part of the silicon nitride film.

31-32. (canceled)

33. The apparatus according to claim 26, wherein the control unit controls the processing gas supply unit to maintain a pressure within the processing container in a range of 10 Pa to 60 Pa during the plasma processing using the plasma.

34. The apparatus according to claim 26, wherein the control unit controls a supply flow rate of the hydrogen gas to control film stress of the silicon nitride film.

35. The apparatus according to claim 26, wherein the plasma excitation unit supplies microwaves to excite the processing gas.

36. The apparatus according to claim 35, wherein the control unit controls a power of the microwaves to control film stress of the silicon nitride film.

37. The apparatus according to claim 26, wherein the processing gas includes a raw material gas to form the silicon nitride film and a plasma excitation gas to generate the plasma, and
the control units controls the processing gas supply unit and the plasma excitation unit to initiate supply of a power of the microwaves (μ waves) is initiated to generate the plasma after the processing gas is stabilized to a desired processing condition.

38. The apparatus according to claim 26, wherein the control unit controls the processing gas supply unit such that a ratio of a supply flow rate of the nitrogen gas in relation to a supply flow rate of the silane-based gas in the processing gas to be supplied to the processing container ranges 1 to 1.5.

39. The apparatus according to claim 26, wherein the processing gas includes a raw material gas for forming the silicon nitride film and a plasma excitation gas for generating the plasma,
the plasma excitation unit is provided in an upper portion of the processing container,
a placing unit configured to place the substrate thereon is installed in a lower portion of the processing container,
a plasma excitation gas supply structure and a raw material gas supply structure are provided between the plasma excitation unit and the placing unit, the plasma excitation gas supply structure and the raw material gas supply structure dividing the inside of the processing container and constituting the processing gas supply unit,
the plasma excitation gas supply structure is formed with a plasma excitation gas supply port configured to supply the plasma excitation gas to the plasma excitation unit side region and an opening configured to allow the plasma generated in the plasma excitation unit side region to pass therethrough to the placing unit side region, and
the raw material gas supply structure is formed with a raw material gas supply port configured to supply the raw material gas to the placing unit side and an opening configured to allow the plasma generated in the plasma excitation unit side region to pass therethrough to the placing unit side region.

40. The apparatus according to claim 39, wherein the plasma excitation gas supply structure is located at a position within a distance of 30 mm from the plasma excitation unit.

41. The apparatus according to claim 39, wherein the raw material gas supply port is formed toward a horizontal direction.

42. The apparatus according to claim 41, wherein the raw material gas supply port is formed such that its inner diameter is enlarged from the inside toward the outside thereof in a tapered form.
